(19) United States
(12) Patent Application Publication
(10) Pub. No.: US 2025/0169329 A1
(43) Pub. Date: May 22, 2025

(54) ELECTROLUMINESCENT DISPLAY DEVICE

(71) Applicant: LG Display Co., Ltd., Seoul (KR)

(72) Inventor: Choong-Hyo KIM, Paju-si (KR)

(73) Assignee: LG Display Co., Ltd., Seoul (KR)

(21) Appl. No.: 18/953,802

(22) Filed: Nov. 20, 2024

(30) Foreign Application Priority Data
Nov. 21, 2023 (KR) 10-2023-0162226

(51) Int. Cl. H10K 59/80; H10K 59/124

(52) U.S. Cl. CPC H10K 59/80522; H10K 59/124

(57) ABSTRACT

An electroluminescent display device includes a substrate provided with a sub-pixel having an emission area and a contact area; a light-emitting diode provided in the emission area over the substrate and including a first electrode, a light-emitting layer, and a second electrode; a first auxiliary electrode provided in the contact area over the substrate and including a first portion of a first direction and a second portion of a second direction; a plurality of insulation patterns provided over the first auxiliary electrode and spaced apart from each other; and a second auxiliary electrode covering the plurality of insulation patterns and electrically connected to the first auxiliary electrode. The light-emitting layer is separated by the plurality of insulation patterns to thereby expose the second auxiliary electrode, and the second electrode is in contact with the exposed second auxiliary electrode.

### CROSS-REFERENCE TO RELATED APPLICATION

The present application claims priority to Korean Patent Application No. 10-2023-0162226 filed in the Republic of Korea on Nov. 21, 2023, the entire contents of which are hereby expressly incorporated by reference into the present application.

### BACKGROUND

### Field of the Disclosure

The present disclosure relates to a display device, and more particularly, to an electroluminescent display device including a light-emitting diode.

### Discussion of the Background Art

As one of the flat panel display devices, an electroluminescent display device has wide viewing angles, as compared with a liquid crystal display device, because it is self-luminous. The electroluminescent display device also has advantages of a thin thickness, light weight and low power consumption because a backlight unit is not necessary.

In addition, the electroluminescent display device is driven by low voltages of direct current (DC) and has a fast response time. Further, the electroluminescent display device is strong against the external impacts and is used in a wide range of temperatures because its components are solids. Further, the electroluminescent display device can be manufactured at low costs.

The electroluminescent display device can include a plurality of pixels, each of which has a plurality sub-pixels for emitting light of different colors, and can display various color images by allowing the plurality of sub-pixels to selectively emit light. Each sub-pixel includes a light-emitting diode, and the light-emitting diode includes a first electrode, a light-emitting layer, and a second electrode.

Here, the first electrode is provided for each sub-pixel, and the second electrode is provided commonly for all sub-pixels. That is, the second electrode is provided to correspond to an entire display area, so that the second electrode is formed in a relatively large area.

The resistance of the second electrode increases depending on the position, which can cause a difference in resistance. Accordingly, there is a limitation that the luminance of the electroluminescent display device is non-uniform due to the difference in resistance.

### SUMMARY OF THE DISCLOSURE

Accordingly, the present disclosure is to provide an electroluminescent display device that substantially obviates one or more of the limitations and disadvantages described above and associated with the background art.

An object of the present disclosure is to provide an electroluminescent display device having a uniform luminance.

Additional features and aspects will be set forth in the description that follows, and in part will be apparent from the description, or can be learned by practice of the present disclosure provided herein. Other features and aspects of the inventive concepts can be realized and attained by the structure particularly pointed out in the written description, or derivable therefrom, and the claims hereof as well as the appended drawings.

To achieve these and other aspects of the present disclosure, as embodied and broadly described herein, an electroluminescent display device includes a substrate provided with a sub-pixel including an emission area and a contact area; a light-emitting diode provided in the emission area over the substrate and including a first electrode, a light-emitting layer, and a second electrode; a first auxiliary electrode provided in the contact area over the substrate and including a first portion of a first direction and a second portion of a second direction; a plurality of insulation patterns provided over the first auxiliary electrode and spaced apart from each other; and a second auxiliary electrode covering the plurality of insulation patterns and electrically connected to the first auxiliary electrode, wherein the light-emitting layer is separated by the plurality of insulation patterns to thereby expose the second auxiliary electrode, and the second electrode is in contact with the exposed second auxiliary electrode.

In another aspect, an electroluminescent display device includes a substrate provided with a plurality of sub-pixel each including an emission area, and sharing a contact area; a light-emitting diode provided in the emission area over the substrate and including a first electrode, a light-emitting layer, and a second electrode; a first auxiliary electrode provided in the contact area over the substrate; a plurality of insulation patterns over the first auxiliary electrode and spaced apart from each other; and a second auxiliary electrode covering the plurality of insulation patterns and electrically connected to the first auxiliary electrode, wherein the light-emitting layer and the second electrode extend to the contact area, in which the light-emitting layer is separated by the plurality of insulation patterns to thereby expose the second auxiliary electrode, and the second electrode is in contact with the exposed second auxiliary electrode.

It is to be understood that both the foregoing general description and the following detailed description are examples and are intended to provide further explanation of the inventive concepts as claimed.

### BRIEF DESCRIPTION OF THE DRAWINGS

The accompanying drawings, which are included to provide a further understanding of the present disclosure and which are incorporated in and constitute a part of this application, illustrate aspects of the disclosure and together with the description serve to explain various principles of the present disclosure.

In the drawings:

FIG. 1 is an example of an equivalent circuit diagram of one sub-pixel SP of an electroluminescent display device according to an embodiment of the present disclosure;

FIG. 2 is a schematic plan view of an electroluminescent display device according to an embodiment of the present disclosure;

FIG. 3 is a cross-sectional view of line I-I′ of FIG. 2;

FIG. 4 is a schematic plan view of another electroluminescent display device according to an embodiment of the present disclosure;

FIG. 5 is a cross-sectional view of line II-II′ of FIG. 4;

FIG. 6 is a schematic plan view of a contact area of an electroluminescent display device according to a first embodiment of the present disclosure;

FIG. 7 is a cross-sectional view corresponding to line IIIA-IIIA′ and line IIIB-IIIB′ of FIG. 6;

FIGS. 8A to 8I are schematic cross-sectional views of a contact area in steps of manufacturing an electroluminescent display device according to the first embodiment of the present disclosure;

FIG. 9 is a schematic plan view of a contact area of an electroluminescent display device repaired according to an embodiment of the present disclosure;

FIG. 10 is a cross-sectional view corresponding to line IV-IV′ of FIG. 9;

FIG. 11 is a schematic plan view of a contact area of an electroluminescent display device repaired according to another embodiment of the present disclosure;

FIG. 12 is a cross-sectional view corresponding to line V-V′ of FIG. 11;

FIG. 13 is a schematic plan view of a contact area of an electroluminescent display device according to a second embodiment of the present disclosure;

FIG. 14 is a cross-sectional view corresponding to line VI-VI′ of FIG. 13;

FIG. 15 is a schematic plan view of a contact area of an electroluminescent display device according to a third embodiment of the present disclosure;

FIG. 16 is a cross-sectional view corresponding to line VIIA-VIIA′ and line VIIB-VIIB′ of FIG. 15; and

FIG. 17 is a schematic plan view of a contact area of an electroluminescent display device according to a fourth embodiment of the present disclosure.

### DETAILED DESCRIPTION OF THE EMBODIMENTS

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes (e.g., sizes, lengths, widths, heights, thicknesses, locations, radii, diameters, and areas), ratios, angles, numbers, and the like disclosed herein, including those illustrated in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein or can be briefly discussed.

The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

When terms such as “including,” “having,” “comprising” and the like mentioned in this disclosure are used, other parts can be added unless the term “only” is used herein. Further, when a component is expressed as being singular, being plural is included unless otherwise specified.

In analyzing a component, an error range is interpreted as being included even when there is no explicit description. Any implementation described herein as an “example” is not necessarily to be construed as preferred or advantageous over other implementations.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

The terms, such as “below,” “lower,” “above,” “upper” and the like, may be used herein to describe a relationship between element(s) as illustrated in the drawings. It will be understood that the terms are spatially relative and based on the orientation depicted in the drawings.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

Although the terms first, second, “A,” “B,” “(a),” “(b),” and the like are used to describe various components, these components are not substantially limited by these terms. These terms are used only to distinguish one component from another component, and may not define any order or sequence. Therefore, a first component described below can substantially be a second component within the technical spirit of the present disclosure.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Features of various embodiments of the present disclosure can be partially or entirely united or combined with each other, technically various interlocking and driving are possible, and each of the embodiments can be independently implemented with respect to each other or implemented together in a related relationship. Further, the term “can” fully encompasses all the meanings and coverages of the term “may.”

Hereinafter, example embodiments of the present disclosure will be described in detail with reference to accompanying drawings. All the components of each display device according to all embodiments of the present disclosure are operatively coupled and configured.

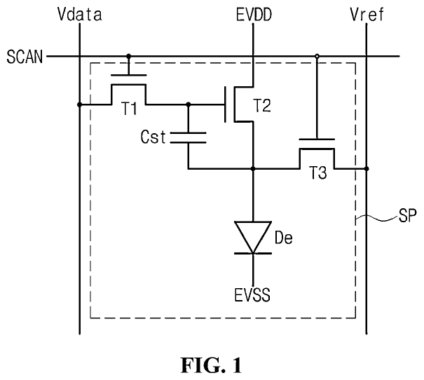

An electroluminescent display device according to embodiments of the present disclosure includes a plurality of pixels arranged in the form of a matrix (or any other form) in a display area, and each pixel includes a plurality of sub-pixels. Each sub-pixel has the same or substantially the same configuration as other sub-pixels. Now, one example of the configuration of such sub-pixel of the electroluminescent display device will be described with reference to FIG. 1, but other configurations are possible.

FIG. 1 is an example of an equivalent circuit diagram of one sub-pixel SP of an electroluminescent display device according to an embodiment of the present disclosure. The display device can include a plurality of pixels, each pixel having a plurality of sub-pixels SP, where each sub-pixel SP has the configuration of FIG. 1.

As shown in FIG. 1, the sub-pixel SP of the electroluminescent display device according to the embodiment of the present disclosure can include first, second, and third transistors T1, T2, and T3, a storage capacitor Cst, and a light-emitting diode De. The first, second, and third transistors T1, T2, and T3 can be a switching transistor T1, a driving transistor T2, and a sensing transistor T3, respectively. The switching transistor T1, the driving transistor T2, and the sensing transistor T3 can be n-type transistors. However, the present disclosure is not limited thereto. Alternatively, the switching transistor T1, the driving transistor T2, and the sensing transistor T3 can be p-type transistors or other types of transistors. As an example, the switching transistor T1, the driving transistor T2, and the sensing transistor T3 can be transistors of the same type or transistors of different types.

A gate line supplying a scan signal (or gate signal) SCAN and a data line supplying a data signal Vdata can cross each other, and the switching transistor T1 can be disposed at a crossing point of the gate line and the data line. A gate of the switching transistor T1 can be connected to the gate line to receive the gate signal SCAN, and a drain of the switching transistor T1 can be connected to the data line to receive the data signal Vdata.

In addition, a gate of the driving transistor T2 can be connected to a source of the switching transistor T1 and a first capacitor electrode of the storage capacitor Cst. A drain of the driving transistor T2 can be connected to a high potential line supplying a high potential voltage EVDD, and a source of the driving transistor T2 can be connected to an anode of the light-emitting diode De, a second capacitor electrode of the storage capacitor Cst, and a source of the sensing transistor T3.

A gate of the sensing transistor T3 can be connected to the gate line, and a drain of the sensing transistor T3 can be connected to a reference line supplying a reference voltage Vref. Alternatively, the gate of the sensing transistor T3 can be connected to a separate sensing line.

Here, the source and drain locations of each of the transistors T1, T2, and T3 are not limited thereto, and the locations can be interchanged or varied.

Meanwhile, a cathode of the light-emitting diode De can be connected to a low potential line supplying a low potential voltage EVSS. Alternatively, the cathode of the light-emitting diode De can be connected to a ground voltage. As a variation, instead of the light-emitting diode De, another type of light-emitting element can be used.

During an emission period of one frame, the switching transistor T1 can be switched according to the gate signal SCAN transmitted through the gate line to thereby provide the gate of the driving transistor T2 with the data signal Vdata transmitted through the data line. The driving transistor T2 can be switched according to the data signal Vdata to thereby control a current of the light-emitting diode De. In this case, the storage capacitor Cst can maintain charges corresponding to the data signal Vdata for a certain period (e.g., one frame). Accordingly, even if the switching transistor T1 is turned off, the storage capacitor Cst can allow the amount of the current flowing through the light-emitting diode De to be constant and the gray level shown by the light-emitting diode De to be maintained until a next frame.

In addition, one frame can further include a sensing period. During the sensing period, the sensing transistor T3 can be switched according to the gate signal SCAN transmitted through the gate line to thereby provide the source of the driving transistor T2 with the reference voltage Vref. The sensing transistor T3 can detect the voltage change of the source of the driving transistor T2 through the reference line and can calculate the threshold voltage Vth of the driving transistor T2 by comparing the amount of the voltage change with a determination range. Accordingly, by calculating the threshold voltage Vth in real time and compensating for the image data, it is possible to compensate for the change in the characteristics of the driving transistor T2 and reduce or prevent image degradation.

However, the configuration of the sub-pixel of the electroluminescent display device according to the embodiment of the present disclosure is not limited thereto. In some embodiments, the sensing transistor T3 can be omitted. In addition, the number and connection relationship of the transistors, the storage capacitor and/or the light-emitting diode can vary.

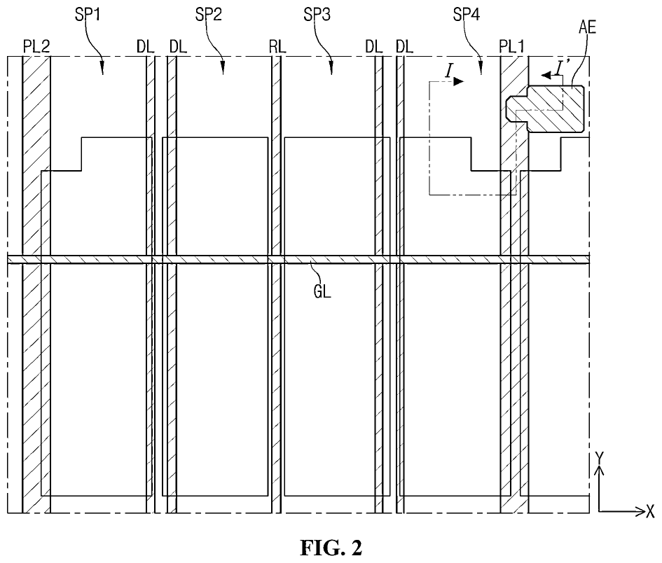

FIG. 2 is a schematic plan view of an electroluminescent display device according to an embodiment of the present disclosure and shows one sub-pixel. The electroluminescent display device according to an embodiment of the present disclosure can be a top emission type display device. Embodiments are not limited thereto. As an example, the electroluminescent display device according to an exemplary embodiment of the present disclosure can be a bottom emission type display device or a dual emission type display device.

As shown in FIG. 2, in an electroluminescent display device according to an embodiment of the present disclosure, a gate line GL can extend in a first direction, which is an X direction. A plurality of data lines DL, a first power line PL1, a second power line PL2, and a reference line RL can extend in a second direction, which is a Y direction. The gate line GL can cross the data lines DL, the first power line PL1, the second power line PL2, and the reference line RL to thereby define a plurality of sub-pixels SP1, SP2, SP3, and SP4. Here, the first power line PL1 can be the low potential line supplying the low potential voltage EVSS of FIG. 1, and the second power line PL2 can be the high potential line supplying the high potential voltage EVDD of FIG. 1.

The gate line GL can pass through each sub-pixel SP1, SP2, SP3, and SP4. However, embodiments of the present disclosure are not limited thereto. Alternatively, the gate line GL can be disposed at a top or bottom portion of each sub-pixel SP1, SP2, SP3, and SP4.

One reference line RL can be disposed between the first and second power lines PL1 and PL2, and two data lines DL can be disposed between the first power line PL1 and the reference line RL and between the second power line PL2 and the reference line RL. Two data lines DL can be disposed adjacent to each other substantially at the center between the reference line RL and the first power line PL1 or second power line PL2, without being limited thereto.

Each sub-pixel SP1, SP2, SP3, and SP4 can have a substantially rectangular shape. However, embodiments of the present disclosure are not limited thereto, and each sub-pixel SP1, SP2, SP3, and SP4 can have other shapes. such as a circular shape, a square shape, an oval shape, an ellipse shape, a polygonal shape, etc.

As described above, one pixel can include the plurality of sub-pixels SP1, SP2, SP3, and SP4. For example, one pixel can include four sub-pixels, for example, first, second, third, and fourth sub-pixels SP1, SP2, SP3, and SP4. The first, second, third, and fourth sub-pixels SP1, SP2, SP3, and SP4 can be sequentially arranged along the first direction. Embodiments are not limited thereto. As an example, the first, second, third, and fourth sub-pixels SP1, SP2, SP3, and SP4 can be arranged along the second direction or a direction between the first direction and the second direction. As an example, the first, second, third, and fourth sub-pixels SP1, SP2, SP3, and SP4 can be arranged in two rows and/or two columns. As an example, one pixel can include two, three or more than four sub-pixels. As an example, the two, three or more than four sub-pixels may be arranged along the first direction, the second direction or a direction between the first direction and the second direction. As an example, the three or more than four sub-pixels may be arranged in a plurality of rows and/or a plurality of columns.

Here, the first sub-pixel SP1 can be a red sub-pixel, the second sub-pixel SP2 can be a green sub-pixel, the third sub-pixel SP3 can be a blue sub-pixel, and the fourth sub-pixel SP4 can be a white sub-pixel. However, embodiments of the present disclosure are not limited thereto. In other embodiments, the number of sub-pixels included in one pixel and/or the arrangement order of the red, green, blue, and white sub-pixels can be changed. As an example, a sub-pixel of other colors may be additionally or alternatively included.

The first, second, third, and fourth sub-pixels SP1, SP2, SP3, and SP4 can have substantially the same area. However, embodiments of the present disclosure are not limited thereto. In other embodiments, the first, second, third, and fourth sub-pixels SP1, SP2, SP3, and SP4 can have different areas from each other.

Here, one power line PL1 or PL2, two data lines DL, or one reference line RL can be disposed substantially between adjacent sub-pixels SP1, SP2, SP3, and SP4. For example, two data lines DL can be disposed between the first and second sub-pixels SP1 and SP2 and between the third and fourth sub-pixels SP3 and SP4, one reference line RL can be disposed between the second and third sub-pixels SP2 and SP3, and one first power line PL1 can be disposed between the fourth sub-pixel SP4 and a first sub-pixel SP1 of a next pixel. In addition, two pixels adjacent to each other in the first direction can be symmetrical with respect to the first power line PL1 or second power line PL2. However, embodiments of the present disclosure are not limited thereto. As an example, two pixels adjacent to each other in the first direction can be unsymmetrical with respect to the first power line PL1 or second power line PL2. As an example, two pixels adjacent to each other in the first direction can have the same or substantially the same configuration, or can have different configurations.

In each sub-pixel SP1, SP2, SP3, and SP4, the light-emitting diode De, the first, second, and third transistors T1, T2, and T3, and the storage capacitor Cst of FIG. 1 can be provided.

The light-emitting diode De can include a first electrode, a light-emitting layer, and a second electrode. The first electrode can be provided at each sub-pixel SP1, SP2, SP3, and SP4. The second electrode can be commonly provided over all sub-pixels SP1, SP2, SP3, and SP4. Embodiments are not limited thereto. As an example, the first electrode can be commonly provided over all sub-pixels SP1, SP2, SP3, and SP4, and the second electrode can be provided at each sub-pixel SP1, SP2, SP3, and SP4. As an example, each of the first electrode and the second electrode can be provided at each sub-pixel SP1, SP2, SP3, and SP4, without being limited thereto.

Meanwhile, an auxiliary electrode AE can be provided to partially overlap the first power line PL1. The auxiliary electrode AE can be provided for each pixel and can be disposed to correspond to the fourth sub-pixel SP4, without being limited thereto.

The auxiliary electrode AE can be connected to the first power line PL1, and the second electrode of the light-emitting diode De can be connected to the auxiliary electrode AE. Accordingly, the second electrode of the light-emitting diode De can be electrically connected to the first power line PL1 through the auxiliary electrode AE. Therefore, the resistance of the second electrode can be reduced, and the luminance of the electroluminescent display device can be uniform.

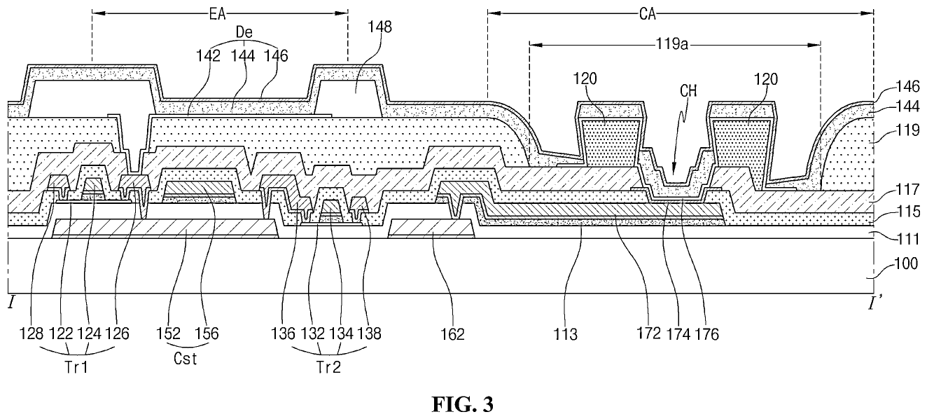

A cross-sectional configuration of the electroluminescent display device according to the embodiment of the present disclosure will be described with reference to FIG. 3.

FIG. 3 is a cross-sectional view of line I-I′ of FIG. 2 and shows a cross-section of one sub-pixel.

As shown in FIG. 3, a sub-pixel of the electroluminescent display device according to the embodiment of the present disclosure can include an emission area EA and a contact area CA provided on a substrate 100. A light-emitting diode De can be provided in the emission area EA, and an auxiliary electrode 172, 174, and 176 can be provided in the contact area CA. The light-emitting diode De can include a first electrode 142, a light-emitting layer 144, and a second electrode 146. The second electrode 146 can also be provided in the contact area CA and be electrically connected to a power line 162 through the auxiliary electrode 172, 174, and 176.

Specifically, a light-blocking layer 152 and the power line 162 can be provided on the substrate 100. The substrate 100 can be formed of a transparent insulating material and, for example, can be a glass substrate or a plastic substrate. Polyimide can be used for the plastic substrate, but embodiments are not limited thereto. Embodiments are not limited thereto. As an example, the substrate 100 can be also formed of an opaque material. As an example, the substrate 100 can be formed of a flexible material or a rigid material.

The light-blocking layer 152 can be disposed in the emission area EA, and a part of the light-blocking layer 152 can function as a first capacitor electrode, without being limited thereto. The power line 162 can be disposed substantially between the emission area EA and the contact area CA. Here, the power line 162 can correspond to the first power line PL1 of FIG. 2 and can be a low potential power line providing a low potential voltage.

The light-blocking layer 152 can be provided on the same layer and of the same material as the power line 162. The light-blocking layer 152 and the power line 162 can be formed of a conductive material such as metal. The light-blocking layer 152 and the power line 162 can be formed of one or more of: aluminum (Al), copper (Cu), molybdenum (Mo), titanium (Ti), chromium (Cr), nickel (Ni), tungsten (W), and an alloy thereof. For example, the light-blocking layer 152 and the power line 162 can have a double-layered structure including a lower layer of a molybdenum-titanium alloy (MoTi) and an upper layer of copper (Cu), and the upper layer can have a thicker thickness than the lower layer. However, embodiments of the present disclosure are not limited thereto. In other embodiments, the light-blocking layer 152 and the power line 162 can have a single-layered structure, a triple-layered structure or a multiple-layered structure. Embodiments are not limited thereto. As an example, the light-blocking layer 152 can be provided on a different layer from the power line 162, and/or the light-blocking layer 152 can be made of a different material from the power line 162. As an example, the light-blocking layer 152 may be omitted depending on the design.

A buffer layer 111 of an insulating material can be provided on the light-blocking layer 152 and the power line 162. The buffer layer 111 can be disposed over substantially an entire surface of the substrate 100. The buffer layer 111 can be formed of an inorganic insulating material, such as silicon oxide (SiO₂) or silicon nitride (SiNₓ), and can be formed as a single layer or multiple layers.

A first semiconductor layer 122 and a second semiconductor layer 132 can be patterned and provided on the buffer layer 111. The first semiconductor layer 122 and the second semiconductor layer 132 can be disposed to correspond to the emission area EA, without being limited thereto. As an example, the first semiconductor layer 122 and/or the second semiconductor layer 132 can be disposed to at least partially correspond to the contact area CA.

The first semiconductor layer 122 can overlap the light-blocking layer 152, and the second semiconductor layer 132 can be spaced apart from the light-blocking layer 152. As an example, the first semiconductor layer 122 can overlap the light-blocking layer 152 in a vertical direction, and the second semiconductor layer 132 can be spaced apart from the light-blocking layer 152 in a lateral direction. As an example, the second semiconductor layer 132 does not overlap the light-blocking layer 152. The light-blocking layer 152 can block light incident on the first semiconductor layer 122, and reduce or prevent the first semiconductor layer 122 from deteriorating due to the light. However, embodiments of the present disclosure are not limited thereto. In other embodiments, both the first semiconductor layer 122 and the second semiconductor layer 132 can overlap the light-blocking layer 152 (e.g., in the vertical direction).

The first semiconductor layer 122 and the second semiconductor layer 132 can be formed of an oxide semiconductor material.

Alternatively, the first semiconductor layer 122 and the second semiconductor layer 132 can be formed of polycrystalline silicon, or other semiconductor materials such as amorphous silicon, a compound semiconductor material, an organic semiconductor material, etc. In this case, both end portions of each of the first semiconductor layer 122 and the second semiconductor layer 132 can be doped with impurities.

A gate insulation layer 113 of an insulating material can be disposed on the buffer layer 111 provided with the first semiconductor layer 122 and the second semiconductor layer 132 thereon, and a first gate electrode 124, a second gate electrode 134, a second capacitor electrode 156, and a first auxiliary electrode 172 can be disposed on the gate insulation layer 113, without being limited thereto. As an example, at least one of the above-mentioned components may be disposed on a different layer.

The gate insulation layer 113 can be patterned to correspond to (e.g., have substantially the same shape as) at least one of or each of the first gate electrode 124, the second gate electrode 134, the second capacitor electrode 156, and the first auxiliary electrode 172. However, embodiments of the present disclosure are not limited thereto. In other embodiments, the gate insulation layer 113 can be disposed over substantially the entire surface of the substrate 100.

The gate insulation layer 113 can be formed of an inorganic insulating material, such as silicon oxide (SiO₂) or silicon nitride (SiNₓ). When the first semiconductor layer 122 and the second semiconductor layer 132 are made of an oxide semiconductor material, the gate insulation layer 113 can be formed of silicon oxide (SiO₂), without being limited thereto.

Alternatively, when the first semiconductor layer 122 and the second semiconductor layer 132 are made of polycrystalline silicon, the gate insulation layer 113 can be formed of silicon oxide (SiO₂) or silicon nitride (SiNₓ), without being limited thereto.

The first gate electrode 124, the second gate electrode 134, and the second capacitor electrode 156 can be disposed substantially in the emission area EA, and the first auxiliary electrode 172 can be disposed in the contact area CA.

In this case, the first gate electrode 124 can be disposed to correspond to a center of the first semiconductor layer 122, and the second gate electrode 134 can be disposed to correspond to a center of the second semiconductor layer 132, without being limited thereto. As an example, the first gate electrode 124 can be disposed to correspond to a position other than the center of the first semiconductor layer 122, and/or the second gate electrode 134 can be disposed to correspond to a position other than the center of the second semiconductor layer 132. Accordingly, the first gate electrode 124 can overlap the light-blocking layer 152 (e.g., in the vertical direction), and the second gate electrode 134 can be spaced part from the light-blocking layer 152 (e.g., in the lateral direction). Alternatively, when the second semiconductor layer 132 overlaps the light-blocking layer 152, the second gate electrode 134 can overlap the light-blocking layer 152.

In addition, the second capacitor electrode 156 can overlap the light-blocking layer 152. The light-blocking layer 152 and the second capacitor electrode 156 overlapping each other can constitute a storage capacitor Cst with the buffer layer 111 and the gate insulation layer 113 interposed therebetween as a dielectric.

Meanwhile, the first auxiliary electrode 172 can overlap the power line 162 and be in contact with the power line 162 through a contact hole provided in the gate insulation layer 113 and the buffer layer 111. Embodiments are not limited thereto. As an example, the first auxiliary electrode 172 may not overlap the power line 162, and may be in contact with the power line 162, for example, through a separate electrode.

The first gate electrode 124, the second gate electrode 134, the second capacitor electrode 156, and the first auxiliary electrode 172 can be formed of a conductive material such as metal. The first gate electrode 124, the second gate electrode 134, the second capacitor electrode 156, and the first auxiliary electrode 172 can be formed of one or more of: aluminum (Al), copper (Cu), molybdenum (Mo), titanium (Ti), chromium (Cr), nickel (Ni), tungsten (W), and an alloy thereof, without being limited thereto. For example, the first gate electrode 124, the second gate electrode 134, the second capacitor electrode 156, and the first auxiliary electrode 172 can have a double-layered structure. For example, the first gate electrode 124, the second gate electrode 134, the second capacitor electrode 156, and the first auxiliary electrode 172 can have a double-layered structure, including a lower layer of a molybdenum-titanium alloy (MoTi) and an upper layer of copper (Cu), and the upper layer can be thicker than the lower layer. However, embodiments of the present disclosure are not limited thereto. In other embodiments, the first gate electrode 124, the second gate electrode 134, the second capacitor electrode 156, and the first auxiliary electrode 172 can have a single-layered structure or a triple-layered structure or a multiple-layered structure. As an example, the first gate electrode 124, the second gate electrode 134, the second capacitor electrode 156, and the first auxiliary electrode 172 may have the same structure or different structures.

A first passivation layer 115 of an insulating material can be provided on the first gate electrode 124, the second gate electrode 134, the second capacitor electrode 156, and the first auxiliary electrode 172. The first passivation layer 115 can be disposed over substantially the entire surface of the substrate 100. The first passivation layer 115 can be an interlayer insulation layer and can be formed of an inorganic insulating material, such as silicon oxide (SiO₂) or silicon nitride (SiNₓ).

The first passivation layer 115 can have a contact hole exposing the first auxiliary electrode 172 in the contact area CA.

First source and first drain electrodes 126 and 128 and second source and second drain electrodes 136 and 138 can be disposed on the first passivation layer 115. The first source and first drain electrodes 126 and 128 and the second source and second drain electrodes 136 and 138 can be formed of a conductive material such as metal. The first source and first drain electrodes 126 and 128 and the second source and second drain electrodes 136 and 138 can be formed of one or more of: aluminum (Al), copper (Cu), molybdenum (Mo), titanium (Ti), chromium (Cr), nickel (Ni), tungsten (W), and an alloy thereof, without being limited thereto. For example, the first source and first drain electrodes 126 and 128 and the second source and second drain electrodes 136 and 138 can have a double-layered structure. For example, the first source and first drain electrodes 126 and 128 and the second source and second drain electrodes 136 and 138 can have a double-layered structure, including a lower layer of a molybdenum-titanium alloy (MoTi) and an upper layer of copper (Cu), and the upper layer can be thicker than the lower layer. However, embodiments of the present disclosure are not limited thereto. In other embodiments, the first source and first drain electrodes 126 and 128 and the second source and second drain electrodes 136 and 138 can have a single-layered structure, a triple-layered structure or a multiple-layered structure.

The first source electrode 126 and the first drain electrode 128 can be spaced apart from each other with the first gate electrode 124 positioned therebetween and can be in contact with the both end portions of the first semiconductor layer 122 through contact holes provided in the first passivation layer 115. In addition, the second source electrode 136 and the second drain electrode 138 can be spaced apart from each other with the second gate electrode 134 positioned therebetween and can be in contact with the both end portions of the second semiconductor layer 132 through contact holes provided in the first passivation layer 115.

The first semiconductor layer 122, the first gate electrode 124, the first source electrode 126, and the first drain electrode 128 can form a first thin film transistor Tr1. The second semiconductor layer 132, the second gate electrode 134, the second source electrode 136, and the second drain electrode 138 can form a second thin film transistor Tr2.

The first and second thin film transistors Tr1 and Tr2 can have a coplanar structure in which the gate electrode 124 and 134 and the source and drain electrodes 126, 128, 136, and 138 can be located at the same side with respect to the semiconductor layer 122 and 132, for example, disposed over the semiconductor layer 122 and 132.

Alternatively, the first and second thin film transistors Tr1 and Tr2 can have an inverted staggered structure in which the gate electrode and the source and drain electrodes can be located at different sides with respect to the semiconductor layer. For example, the gate electrode can be disposed under the semiconductor layer, and the source and drain electrodes can be disposed over the semiconductor layer. In this case, the semiconductor layer can be formed of oxide semiconductor or amorphous silicon, without being limited thereto.

The first thin film transistor Tr1 can be the driving transistor T2 of FIG. 1, and the second thin film transistor Tr2 can be the sensing transistor T3 of FIG. 1. In addition, at least one thin film transistor having substantially the same structure as the first and second thin film transistors Tr1 and Tr2, for example, the switching transistor T1 of FIG. 1, can be further provided on the substrate 100. Embodiments are not limited thereto. As an example, the switching transistor T1 of FIG. 1 may have a different structure from the first and second thin film transistors Tr1 and Tr2.

Meanwhile, the first source electrode 126 and the second source electrode 136 can be in contact with the light-blocking layer 152 through contact holes provided in the first passivation layer 115 and the buffer layer 111. Accordingly, the first and second thin film transistors Tr1 and Tr2 can be connected to the storage capacitor Cst.

Next, a second auxiliary electrode 174 can be disposed on the first passivation layer 115 in the contact area CA. The second auxiliary electrode 174 can be in contact with the first auxiliary electrode 172 through a contact hole provided in the first passivation layer 115. A thickness of the second auxiliary electrode 174 can be smaller than a thickness of the first auxiliary electrode 172, or may be equal to or greater than the thickness of the first auxiliary electrode 172.

The second auxiliary electrode 174 can be formed of a conductive material such as metal. For example, the second auxiliary electrode 174 can be formed of one or more of: molybdenum (Mo), titanium (Ti), chromium (Cr), nickel (Ni), tungsten (W), and an alloy thereof. Alternatively, the second auxiliary electrode 174 can be formed of a transparent conductive material. For example, the second auxiliary electrode 174 can be formed of indium tin oxide (ITO) or indium zinc oxide (IZO). The second auxiliary electrode 174 can have a single-layered structure, or a multiple-layered structure.

A second passivation layer 117 of an insulating material can be provided on the first source and first drain electrodes 126 and 128, the second source and second drain electrodes 136 and 138, and the second auxiliary electrode 174. The second passivation layer 117 can be disposed over substantially the entire surface of the substrate 100. The second passivation layer 117 can be a protection layer. The second passivation layer 117 can be formed of an inorganic insulating material, such as silicon oxide (SiO₂) or silicon nitride (SiNₓ). A thickness of the second passivation layer 117 can be thicker than a thickness of the first passivation layer 115, or may be equal to or thinner than the thickness of the first passivation layer 115.

The second passivation layer 117 can have a contact hole CH exposing the second auxiliary electrode 174 in the contact area CA.

An overcoat layer 119 of an insulating material can be provided on the second passivation layer 117. The overcoat layer 119 can be disposed over substantially the entire surface of the substrate 100. The overcoat layer 119 and the second passivation layer 117 can have a contact hole exposing the first source electrode 126 in the emission area EA. In addition, the overcoat layer 119 can have an opening 119a corresponding to the first and second auxiliary electrodes 172 and 174 in the contact area CA. The contact hole CH of the second passivation layer 117 can be disposed in the opening 119a, and the contact hole CH can be spaced apart from the overcoat layer 119, e.g., in a lateral direction.

The overcoat layer 119 can be a planarization layer. The overcoat layer 119 can be formed of an organic insulating material such as photosensitive acrylic polymer (photo acryl), without being limited thereto. The overcoat layer 119 can eliminate a step difference due to the layers thereunder and can have a substantially flat top surface. However, embodiments of the present disclosure are not limited thereto.

Meanwhile, a plurality of insulation patterns 120 of an insulating material can be provided on the second passivation layer 117 in the contact area CA and be spaced apart from each other. The plurality of insulation patterns 120 can be disposed in the opening 119a of the overcoat layer 119 and be spaced apart from the overcoat layer 119. The contact hole CH can be disposed between adjacent insulation patterns 120 and expose the second auxiliary electrode 174.

Each insulation pattern 120 can have a reversely-inclined side surface. Accordingly, a top side of each insulation pattern 120 can have a wider width than a bottom side.

The insulation patterns 120 can be formed of an organic insulating material, or an inorganic insulating material. In this case, the insulation patterns 120 can be formed of the same material as the overcoat layer 119. However, embodiments of the present disclosure are not limited thereto. Alternatively, the insulation patterns 120 can be formed of a different material from the overcoat layer 119.

A third auxiliary electrode 176 can be provided on the insulation patterns 120 in the contact area CA. The third auxiliary electrode 176 can be disposed in the opening 119a of the overcoat layer 119 and be spaced apart from the overcoat layer 119, e.g., in a lateral direction.

The third auxiliary electrode 176 can cover the insulation patterns 120 and be in contact with top and side surfaces of each insulation pattern 120. The third auxiliary electrode 176 can be in contact with the second auxiliary electrode 174 exposed through the contact hole CH between adjacent insulation patterns 120.

Here, the first, second, and third auxiliary electrodes 172, 174, and 176 can correspond to the auxiliary electrode AE of FIG. 2, and the second auxiliary electrode 174 can be omitted.

The first electrode 142 can be disposed on the overcoat layer 119 in the emission area EA and can be formed of a conductive material having relatively high work function. The first electrode 142 can be in contact with the first source electrode 126 through the contact hole provided in the overcoat layer 119 and the second passivation layer 117.

For example, the first electrode 142 can include a transparent conductive material such as indium tin oxide (ITO) or indium zinc oxide (IZO) or include titanium (Ti). However, embodiments of the present disclosure are not limited thereto.

Meanwhile, as described above, the electroluminescent display device according to the embodiment of the present disclosure can be a top emission type display device, in which light from the light-emitting layer 144 is output toward a direction opposite the substrate 100, for example, output to the outside through the second electrode 146. In this case, the first electrode 142 can have a multi-layered structure including a material with relatively high reflectance. For example, the first electrode 142 can be formed as a structure having relatively high reflectance such as a triple-layered structure of titanium, aluminum, and titanium (Ti/Al/Ti), a triple-layered structure of indium tin oxide, aluminum, and indium tin oxide (ITO/Al/ITO), a triple-layered structure of indium tin oxide, silver, and indium tin oxide (ITO/Ag/ITO), or a triple-layered structure of indium tin oxide, silver alloy, and indium tin oxide (ITO/Ag alloy/ITO). Here, the silver alloy can be an alloy of silver-palladium-copper (APC).

A bank 148 of an organic insulating material can be disposed on the first electrode 142. The bank 148 can overlap edges of the first electrode 142 and cover the edges of the first electrode 142. The bank 148 can expose a portion (e.g., a central portion) of the first electrode 142.

The bank 148 may not be provided in the contact area CA. In this case, the bank 148 can have a hole corresponding to the contact area CA.

Next, the light-emitting layer 144 can be provided on the first electrode 142 exposed by the bank 148. The light-emitting layer 144 can be disposed over substantially the entire surface of the substrate 100. Accordingly, in the emission area EA, the light-emitting layer 144 can be in contact with the first electrode 142 and also in contact with side and top surfaces of the bank 148.

Additionally, in the contact area CA, the light-emitting layer 144 can be in contact with top and side surfaces of the overcoat layer 119 and can be separated by the insulation patterns 120 having the reversely-inclined side surfaces. Accordingly, the light-emitting layer 144 can expose the third auxiliary electrode 176 formed on the side surface of the insulation pattern 120.

The light-emitting layer 144 can emit white light and can include at least one hole auxiliary layer, at least one light-emitting material layer, and at least one electron auxiliary layer constituting one light-emitting unit. The hole auxiliary layer can include at least one of a hole injection layer (HIL) and a hole transport layer (HTL). The electron auxiliary layer can include at least one of an electron injection layer (EIL) and an electron transport layer (ETL). As an example, at least one of the at least one hole auxiliary layer and the at least one electron auxiliary layer may be omitted.

The light-emitting layer 144 can have a stack structure in which two or more light-emitting units emitting light of different colors are stacked, and a charge generation layer (CGL) can be provided between two light-emitting units.

The second electrode 146 of a conductive material with relatively low work function can be provided on the light-emitting layer 144. The second electrode 146 can be disposed over substantially the entire surface of the substrate 100.

The second electrode 146 can be formed of aluminum (Al), magnesium (Mg), silver (Ag), or an alloy thereof, without being limited thereto. In this case, the second electrode 146 can have a relatively thin thickness such that light from the light-emitting layer 144 can be transmitted therethrough. For example, the second electrode 146 can have a thickness of 5 nm to 10 nm, but embodiments of the present disclosure are not limited thereto.

Alternatively, the second electrode 146 can be formed of a transparent conductive material such as indium gallium oxide (IGO) or IZO, without being limited thereto.

The second electrode 146 can be in contact with a top surface of the light-emitting layer 144. In the contact area CA, the second electrode 146 may not be separated by the insulation patterns 120. The second electrode 146 can be provided along the top and side surfaces of the insulation pattern 120 and be in contact with the third auxiliary electrode 176 exposed on the side surface of the insulation pattern 120. This will be described in detail later.

The first electrode 142, the light-emitting layer 144, and the second electrode 146 of the emission area EA can constitute the light-emitting diode De. Here, the first electrode 142 can serve as an anode, and the second electrode 146 can serve as a cathode. However, embodiments of the present disclosure are not limited thereto. In other embodiments, the first electrode 142 can serve as a cathode, and the second electrode 146 can serve as an anode.

A capping layer can be formed on the second electrode 146 over substantially the entire surface of the substrate 100. The capping layer can be formed of an insulating material having a relatively high refractive index, without being limited thereto. The wavelength of light traveling along the capping layer can be amplified by surface plasma resonance. Thus, the intensity of the peak can be increased, thereby improving the light efficiency in the top-emission type electroluminescent display device. For example, the capping layer can be formed as a single layer of an organic layer or an inorganic layer, or can be formed as organic/inorganic stacked layers.

In addition, an encapsulation layer can be provided on the capping layer. The encapsulation layer can protect the light-emitting diode De from external moisture or oxygen. The encapsulation layer can include at least one inorganic layer and at least one organic layer.

As described above, the electroluminescent display device according to the embodiment of the present disclosure can be the top emission type display device, in which light from the light-emitting layer 144 of the light-emitting diode De is output toward a direction opposite the substrate 100, for example, output to the outside through the second electrode 146. The top emission type display device can have a wider emission area than a bottom emission type display device of the same size, which can improve luminance and reduce power consumption.

By the way, to transmit light, the second electrode 146 should be formed of a metal material to have a thin thickness or formed of a transparent conductive material. According to this, the resistance of the second electrode 146 can increase, and there is a difference of the resistance depending on locations. Therefore, in the embodiment of the present disclosure, to reduce the resistance of the second electrode 146, the second electrode 146 can be electrically connected to the power line 162 through the auxiliary electrode 172, 174, and 176.

In this case, the light-emitting layer 144 can be disposed between the second electrode 146 and the auxiliary electrode 172, 174, and 176. Since the light-emitting layer 144 has insulating properties and acts as a resistor, contact properties between the second electrode 146 and the auxiliary electrode 172, 174, and 176 can be deteriorated.

Accordingly, in the embodiment of the present disclosure, by forming the insulation patterns 120 having the reversely-inclined side surfaces and the third auxiliary electrode 176 covering the insulation patterns 120 between the second electrode 146 and the first and second auxiliary electrodes 172 and 174, more particularly, between the light-emitting layer 144 and the first and second auxiliary electrodes 172 and 174 in the contact area CA, the light-emitting layer 144 can be separated, and the second electrode 146 can be in direct contact with the third auxiliary electrode 176 on the side surface of the insulation pattern 120.

Therefore, the contact properties between the second electrode 146 and the first, second, and third auxiliary electrodes 172, 174, and 176 can be increased, and a difference in resistance of the second electrode 146 can be reduced or prevented, so that the luminance of the electroluminescent display device can be made uniform.

Meanwhile, an electroluminescent display device according to the embodiment of the present disclosure can further include a transparent area.

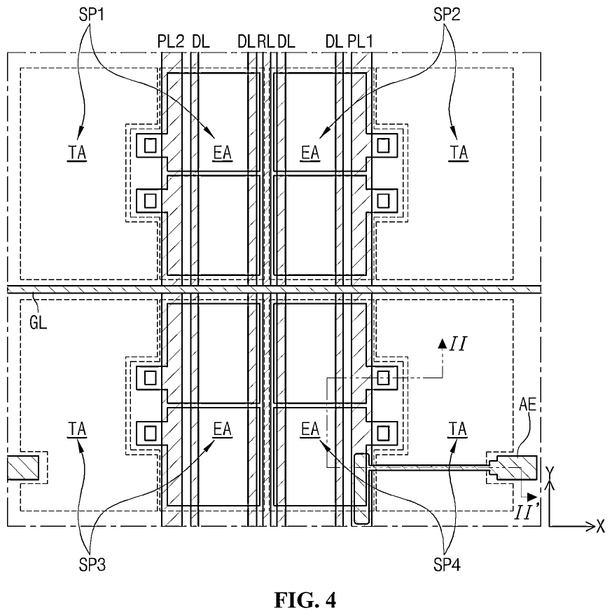

FIG. 4 is a schematic plan view of another electroluminescent display device according to an embodiment of the present disclosure and shows one sub-pixel. Another electroluminescent display device according to an embodiment of the present disclosure can be a transparent display device including an emission area and a transparent area.

As shown in FIG. 4, in another electroluminescent display device according to an embodiment of the present disclosure, a gate line GL can extend in a first direction, which is an X direction. A plurality of data lines DL, a first power line PL1, a second power line PL2, and a reference line RL can extend in a second direction, which is a Y direction. The gate line GL can cross the data lines DL, the first power line PL1, the second power line PL2, and the reference line RL to thereby define a plurality of sub-pixels SP1, SP2, SP3, and SP4. Here, the first power line PL1 can be the low potential line supplying the low potential voltage EVSS of FIG. 1, and the second power line PL2 can be the high potential line supplying the high potential voltage EVDD of FIG. 1.

The gate line GL can be disposed between adjacent sub-pixels SP1, SP2, SP3, and SP4 along the second direction. However, embodiments of the present disclosure are not limited thereto. As an example, the gate line GL can be disposed over at least one of the sub-pixels SP1, SP2, SP3, and SP4.

One reference line RL can be disposed between the first and second power lines PL1 and PL2, and two data lines DL can be disposed between the first power line PL1 and the reference line RL and between the second power line PL2 and the reference line RL.

Each sub-pixel SP1, SP2, SP3, and SP4 can have a substantially rectangular shape. However, embodiments of the present disclosure are not limited thereto, and each sub-pixel SP1, SP2, SP3, and SP4 can have other shapes.

As described above, one pixel can include the plurality of sub-pixels SP1, SP2, SP3, and SP4. For example, one pixel can include four sub-pixels, for example, first, second, third, and fourth sub-pixels SP1, SP2, SP3, and SP4. The first, second, third, and fourth sub-pixels SP1, SP2, SP3, and SP4 can be arranged in a pentile shape. For example, the first and second sub-pixels SP1 and SP2 can be disposed adjacent to each other in the first direction, the third and fourth sub-pixels SP3 and SP4 can be disposed adjacent to each other in the first direction, the first and third sub-pixels SP1 and SP3 can be disposed adjacent to each other in the second direction, and the second and fourth sub-pixels SP2 and SP4 can be disposed adjacent to each other in the second direction.

Here, the first sub-pixel SP1 can be a green sub-pixel, the second sub-pixel SP2 can be a white sub-pixel, the third sub-pixel SP3 can be a blue sub-pixel, and the fourth sub-pixel SP4 can be a red sub-pixel. However, embodiments of the present disclosure are not limited thereto. In other embodiments, the arrangement order of the red, green, blue, and white sub-pixels can be changed. As an example, a sub-pixel of other colors may be additionally or alternatively included.

The first, second, third, and fourth sub-pixels SP1, SP2, SP3, and SP4 can have substantially the same area. However, embodiments of the present disclosure are not limited thereto. In other embodiments, at least one of the first, second, third, and fourth sub-pixels SP1, SP2, SP3, and SP4 can have a different area from others. Alternatively, the first, second, third, and fourth sub-pixels SP1, SP2, SP3, and SP4 can have different areas from each other.

Each of the first, second, third, and fourth sub-pixels SP1, SP2, SP3, and SP4 can include an emission area EA and a transparent area TA. The emission areas EA of the first, second, third, and fourth sub-pixels SP1, SP2, SP3, and SP4 can be disposed adjacent to each other. Accordingly, the emission areas EA of the first and second sub-pixels SP1 and SP2 can be disposed between the transparent areas TA of the first and second sub-pixels SP1 and SP2, and the emission areas EA of the third and fourth sub-pixels SP3 and SP4 can be disposed between the transparent areas TA of the third and fourth sub-pixels SP3 and SP4.

Here, the data line DL, the first power line PL1, and the second power line PL2 can be disposed to correspond to the emission area EA of the first, second, third, and fourth sub-pixels SP1, SP2, SP3, and SP4. As an example, at least one or all of the data line DL, the first power line PL1, and the second power line PL2 can be disposed to overlap the emission area EA of the first, second, third, and fourth sub-pixels SP1, SP2, SP3, and SP4. The reference line RL can be disposed between the first and second sub-pixels SP1 and SP2 and between the third and fourth sub-pixels SP3 and SP4. Embodiments are not limited thereto. As an example, the reference line RL can be disposed to overlap the first and second sub-pixels SP1 and SP2 or the third and fourth sub-pixels SP3 and SP4, without being limited thereto. As an example, the first power line PL1 can be disposed to correspond to the emission area EA of the fourth sub-pixel SP4. As an example, the first power line PL1 can be disposed over the emission area EA of the fourth sub-pixel SP4 to be adjacent to the transparent areas TA, without being limited thereto. As an example, the first power line PL1 can be disposed over the emission area EA of any of the first, second, third, and fourth sub-pixels SP1, SP2, SP3, and SP4.

In each sub-pixel SP1, SP2, SP3, and SP4, the light-emitting diode De, the first, second, and third transistors T1, T2, and T3, and the storage capacitor Cst of FIG. 1 can be provided.

The light-emitting diode De can include a first electrode, a light-emitting layer, and a second electrode. The first electrode can be provided at each sub-pixel SP1, SP2, SP3, and SP4. The second electrode can be commonly provided over all sub-pixels SP1, SP2, SP3, and SP4. Here, the first electrode of each sub-pixel SP1, SP2, SP3, and SP4 can include two electrode patterns, or may include one electrode pattern or three or more electrode patterns, without being limited thereto.

Meanwhile, an auxiliary electrode AE can be provided to partially overlap the first power line PL1. The auxiliary electrode AE can extend substantially in the first direction, and a portion (e.g., one end) of the auxiliary electrode AE can overlap the first power line PL1. The auxiliary electrode AE can be provided for each pixel and can be disposed to correspond to the transparent area TA of the fourth sub-pixel SP4. As an example, the auxiliary electrode AE can be disposed to correspond to the transparent area TA of the fourth sub-pixel SP4, over which the first power line PL1 is disposed, without being limited thereto.

The auxiliary electrode AE can be connected to the first power line PL1, and the second electrode of the light-emitting diode De can be connected to the auxiliary electrode AE. Accordingly, the second electrode of the light-emitting diode De can be electrically connected to the first power line PL1 through the auxiliary electrode AE. Therefore, the resistance of the second electrode can be reduced, and the luminance of the electroluminescent display device can be uniform.

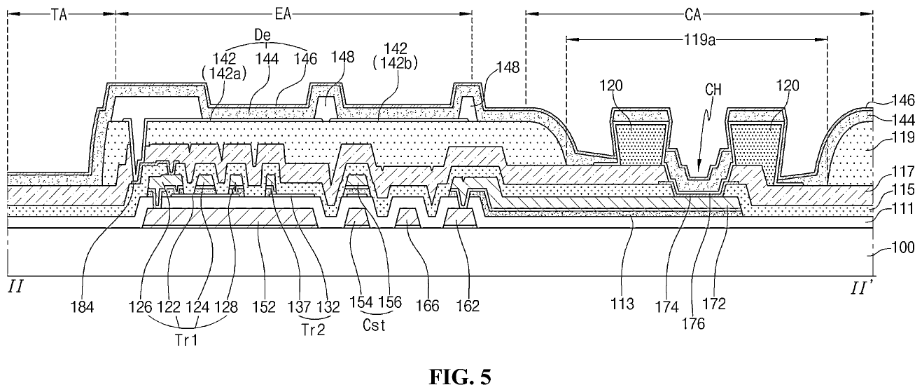

A cross-sectional configuration of another electroluminescent display device according to the embodiment of the present disclosure will be described with reference to FIG. 5.

FIG. 5 is a cross-sectional view of line II-II′ of FIG. 4 and shows a cross-section of one sub-pixel. Another electroluminescent display device according to the embodiment of the present disclosure has substantially the same configuration as that of the previous embodiment of FIG. 3, except for a transparent area, a first electrode, and a connection electrode. The same parts as those of the previous embodiment(s) are designated by the same reference signs/numerals, and explanation for the same parts can be shortened or omitted.

As shown in FIG. 5, a sub-pixel of another electroluminescent display device according to the embodiment of the present disclosure can include an emission area EA, a transparent area TA, and a contact area CA provided on a substrate 100. A light-emitting diode De can be provided in the emission area EA, and an auxiliary electrode 172, 174, and 176 can be provided in the contact area CA. The light-emitting diode De can include a first electrode 142, a light-emitting layer 144, and a second electrode 146, and the second electrode 146 can be electrically connected to a power line 162 through the auxiliary electrode 172, 174, and 176.

Specifically, a light-blocking layer 152, the power line 162, a data line 166, and a first capacitor electrode 154 can be provided on the substrate 100.

The light-blocking layer 152, the power line 162, the data line 166, and the first capacitor electrode 154 can be disposed in the emission area EA. Here, the first capacitor electrode 154 can be connected to the light-blocking layer 152. In addition, the power line 162 can correspond to the first power line PL1 of FIG. 2 and can be a low potential power line providing a low potential voltage.

Meanwhile, according to line II-II′ of FIG. 4, parts of the power line 162 and the data line 166 can also be disposed between the transparent area TA and the light-blocking layer 152, but can be omitted in FIG. 5 for convenience of illustration.

A buffer layer 111 of an insulating material can be provided on the light-blocking layer 152, the power line 162, the data line 166, and the first capacitor electrode 154. The buffer layer 111 can be disposed over substantially an entire surface of the substrate 100.

A first semiconductor layer 122 and a second semiconductor layer 132 can be patterned and provided on the buffer layer 111. The first semiconductor layer 122 and the second semiconductor layer 132 can be disposed to correspond to the emission area EA, without being limited thereto.

The first semiconductor layer 122 and the second semiconductor layer 132 can overlap the light-blocking layer 152. However, embodiments of the present disclosure are not limited thereto. In other embodiments, the first semiconductor layer 122 can overlap the light-blocking layer 152 and the second semiconductor layer 132 can be spaced apart from the light-blocking layer 152, e.g., in a lateral direction.

A gate insulation layer 113 of an insulating material can be disposed on the buffer layer 111 provided with the first semiconductor layer 122 and the second semiconductor layer 132 thereon. A first gate electrode 124, a first source electrode 126, a first drain electrode 128, a second source/drain electrode 137, a second capacitor electrode 156, and a first auxiliary electrode 172 can be disposed on the gate insulation layer 113. In addition, a second gate electrode can be disposed on the gate insulation layer 113.

The gate insulation layer 113 can be patterned to have substantially the same shape as each of the first gate electrode 124, the first source electrode 126, the first drain electrode 128, the second source/drain electrode 137, the second capacitor electrode 156, and the first auxiliary electrode 172. However, embodiments of the present disclosure are not limited thereto. In other embodiments, the gate insulation layer 113 can be disposed over substantially the entire surface of the substrate 100.

The first gate electrode 124, the first source electrode 126, the first drain electrode 128, the second source/drain electrode 137, and the second capacitor electrode 156 can be disposed in the emission area EA, and the first auxiliary electrode 172 can be disposed in the contact area CA. As an example, the first auxiliary electrode 172 can be further partially disposed in the emission area EA, without being limited thereto.

In this case, the first gate electrode 124 can correspond to a center of the first semiconductor layer 122 and can be disposed between the first source electrode 126 and the first drain electrode 128, without being limited thereto. As an example, the first gate electrode 124 can correspond to a position other than the center of the first semiconductor layer 122. The first source electrode 126 and the first drain electrode 128 can be disposed to correspond to the both end portions of the first semiconductor layer 122 and can be in contact with the both end portions of the first semiconductor layer 122 through contact holes provided in the gate insulation layer 113, respectively.

The second gate electrode can be disposed to correspond to a center of the second semiconductor layer 132, without being limited thereto. As an example, the second gate electrode can correspond to a position other than the center of the second semiconductor layer 132. The second source/drain electrode 137 can be disposed to an end portion of the second semiconductor layer 132 and can be in contact with the end portion of the semiconductor layer 132 through a contact hole of the gate insulation layer 113.

In addition, the second capacitor electrode 156 can overlap the first capacitor electrode 154. The first capacitor electrode 154 and the second capacitor electrode 156 overlapping each other can constitute a storage capacitor Cst with the buffer layer 111 and the gate insulation layer 113 interposed therebetween as a dielectric.

A semiconductor pattern can be provided between the first capacitor electrode 154 and the second capacitor electrode 156. The semiconductor pattern can be formed of the same material and on the same layer as the first and second semiconductor layers 122 and 132, without being limited thereto. For example, the semiconductor pattern can overlap the first capacitor electrode 154 and the second capacitor electrode 156 and can be located between the buffer layer 111 and the gate insulation layer 113. Embodiments are not limited thereto. As an example, the semiconductor pattern may be omitted depending on the design.

Meanwhile, the first auxiliary electrode 172 can overlap the power line 162 and be in contact with the power line 162 through a contact hole provided in the gate insulation layer 113 and buffer layer 111.

The first semiconductor layer 122, the first gate electrode 124, the first source electrode 126, and the first drain electrode 128 can form a first thin film transistor Tr1. The second semiconductor layer 132, the second gate electrode, and the second source/second drain electrode 137 can form a second thin film transistor Tr2.

The first thin film transistor Tr1 can be the driving transistor T2 of FIG. 1, and the second thin film transistor Tr2 can be the switching transistor T1 or the sensing transistor T3 of FIG. 1, without being limited thereto. Meanwhile, at least one thin film transistor having substantially the same structure as the first and second thin film transistors Tr1 and Tr2 or having a different structure from the first and second thin film transistors Tr1 and Tr2 can be further provided on the substrate 100.

Here, the first source electrode 126 can be in contact with the light-blocking layer 152 through a contact hole provided in the gate insulation layer 113 and the buffer layer 111.

A first passivation layer 115 of an insulating material can be provided on the first gate electrode 124, the first source electrode 126, the first drain electrode 128, the second source/drain electrode 137, the second capacitor electrode 156, and the first auxiliary electrode 172. The first passivation layer 115 can be disposed over substantially the entire surface of the substrate 100. The first passivation layer 115 can be an interlayer insulation layer and can be formed of an inorganic insulating material, such as silicon oxide (SiO₂) or silicon nitride (SiNₓ), without being limited thereto.

The first passivation layer 115 can have a contact hole exposing the first source electrode 126 in the emission area EA and can have a contact hole exposing the first auxiliary electrode 172 in the contact area CA.

A connection electrode 184 and a second auxiliary electrode 174 can be provided on the first passivation layer 115. The connection electrode 184 can be disposed in the emission area EA, and the second auxiliary electrode 174 can be disposed in the contact area CA. In the emission area EA, the connection electrode 184 can be in contact with the first source electrode 126 through a contact hole provided in the first passivation layer 115. In the contact area CA, the second auxiliary electrode 174 can be in contact with the first auxiliary electrode 172 through a contact hole provided in the first passivation layer 115. A thickness of the second auxiliary electrode 174 can be smaller than a thickness of the first auxiliary electrode 172.

The connection electrode 184 and the second auxiliary electrode 174 can be formed of a conductive material such as metal. Alternatively, the connection electrode 184 and the second auxiliary electrode 174 can be formed of a transparent conductive material. As an example, the connection electrode 184 and the second auxiliary electrode 174 can be formed of the same material or different materials.

A second passivation layer 117 of an insulating material can be provided on the connection electrode 184 and the second auxiliary electrode 174. The second passivation layer 117 can be disposed over substantially the entire surface of the substrate 100. The second passivation layer 117 can be a protection layer. The second passivation layer 117 can be formed of an inorganic insulating material, such as silicon oxide (SiO₂) or silicon nitride (SiNₓ), without being limited thereto. A thickness of the second passivation layer 117 can be thicker than a thickness of the first passivation layer 115.

The second passivation layer 117 can have a contact hole CH exposing the second auxiliary electrode 174 in the contact area CA. As an example, the second passivation layer 117 can cover both end portions of the second auxiliary electrode 174, without being limited thereto. As an example, the second passivation layer 117 can expose at least one end portion or both end portions of the second auxiliary electrode 174, without being limited thereto.

An overcoat layer 119 of an insulating material can be provided on the second passivation layer 117. The overcoat layer 119 can be disposed over substantially in the emission area EA and can be partially or fully removed in the transparent area TA to thereby expose the second passivation layer 117 in the transparent area TA. The overcoat layer 119 and the second passivation layer 117 can have a contact hole exposing the connection electrode 184 in the emission area EA. The contact hole exposing the connection electrode 184 can be spaced apart from the contact hole exposing the first source electrode 126.

In addition, the overcoat layer 119 can have an opening 119a corresponding to the first and second auxiliary electrodes 172 and 174 in the contact area CA. The contact hole CH of the second passivation layer 117 can be disposed in the opening 119a, and the contact hole CH can be spaced apart from the overcoat layer 119, e.g., in a lateral direction.

The overcoat layer 119 can be a planarization layer. The overcoat layer 119 can be formed of an organic insulating material such as photosensitive acrylic polymer (photo acryl), without being limited thereto. The overcoat layer 119 can eliminate a step difference due to the layers thereunder and can have a substantially flat top surface. However, embodiments of the present disclosure are not limited thereto.

Meanwhile, a plurality of insulation patterns 120 of an insulating material can be provided on the second passivation layer 117 in the contact area CA and be spaced apart from each other. The plurality of insulation patterns 120 can be disposed in the opening 119a of the overcoat layer 119 and be spaced apart from the overcoat layer 119, e.g., in a lateral direction. The contact hole CH can be disposed between adjacent insulation patterns 120 and expose the second auxiliary electrode 174.

Each insulation pattern 120 can have a reversely-inclined side surface. Accordingly, a top side of each insulation pattern 120 can have a wider width than a bottom side.

The insulation patterns 120 can be formed of an organic insulating material. In this case, the insulation patterns 120 can be formed of the same material as the overcoat layer 119. However, embodiments of the present disclosure are not limited thereto. Alternatively, the insulation patterns 120 can be formed of a different material from the overcoat layer 119.

A third auxiliary electrode 176 can be provided on the insulation patterns 120 in the contact area CA. The third auxiliary electrode 176 can be disposed in the opening 119a of the overcoat layer 119 and be spaced apart from the overcoat layer 119.

The third auxiliary electrode 176 can cover the insulation patterns 120 and be in contact with top and side surfaces of each insulation pattern 120. The third auxiliary electrode 176 can be in contact with the second auxiliary electrode 174 exposed through the contact hole CH between adjacent insulation patterns 120. As an example, the third auxiliary electrode 176 can be continuously extended from one of the adjacent insulation patterns 120 to another of the adjacent insulation patterns 120. As an example, the third auxiliary electrode 176 can cover the entire side surface of each insulation pattern 120. As an example, the third auxiliary electrode 176 can be further extended on a portion of the second passivation layer 117 adjacent to the insulation pattern 120.

Here, the first, second, and third auxiliary electrodes 172, 174, and 176 can correspond to the auxiliary electrode AE of FIG. 4, and the second auxiliary electrode 174 can be omitted.

The first electrode 142 can be disposed on the overcoat layer 119 in the emission area EA and can be formed of a conductive material having relatively high work function.

For example, the first electrode 142 can include a transparent conductive material such as indium tin oxide (ITO) or indium zinc oxide (IZO) or include titanium (Ti). However, embodiments of the present disclosure are not limited thereto.

Meanwhile, as described above, the electroluminescent display device according to the embodiment of the present disclosure can be a top emission type display device, in which light from the light-emitting layer 144 is output toward a direction opposite the substrate 100, for example, output to the outside through the second electrode 146. In this case, the first electrode 142 can have a multi-layered structure including a material with relatively high reflectance, without being limited thereto.

The first electrode 142 can be divided into two patterns. For example, the first electrode 142 can include a first electrode pattern 142a and a second electrode pattern 142b. The first electrode pattern 142a can be in contact with a first end of the connection electrode 184 through the contact hole provided in the overcoat layer 119 and the second passivation layer 117. In addition, the second electrode pattern 142b can be in contact with a second end of the connection electrode 184 through another contact hole provided in the overcoat layer 119 and the second passivation layer 117. Accordingly, the first electrode pattern 142a and the second electrode pattern 142b can be electrically connected to the first source electrode 126 through the connection electrode 184.

The first and second connection patterns 142a and 142b can reduce or minimize deterioration in image quality by allowing partial light emission through repair when a defect occurs. Specifically, when the defect occurs in a portion corresponding to the first electrode pattern 142a during a manufacturing process or during operation, the first end of the connection electrode 184 connected to the first electrode pattern 142a can be cut using a laser. Accordingly, while light is not emitted in the portion corresponding to the first electrode pattern 142a, light can be emitted in a portion corresponding to the second electrode pattern 142b, thereby preventing a defect in which an entire sub-pixel does not emit light. Embodiments are not limited thereto. As an example, the first electrode 142 may not be divided, or may be divided into three or more patterns.

A bank 148 of an organic insulating material can be disposed on the first electrode 142. The bank 148 can overlap edges of each of the first and second electrode patterns 142a and 142b and cover the edges of each of the first and second electrode patterns 142a and 142b. The bank 148 can expose a central portion of each of the first and second electrode patterns 142a and 142b.

The bank 148 may not be provided in the transparent area TA and the contact area CA. In this case, the bank 148 can have a hole corresponding to the contact area CA.

Next, the light-emitting layer 144 can be provided on the first electrode 142 exposed by the bank 148, for example, on the first and second electrode patterns 142a and 142b. The light-emitting layer 144 can be disposed over substantially the entire surface of the substrate 100. Accordingly, in the emission area EA, the light-emitting layer 144 can be in contact with the first and second electrode patterns 142a and 142b and also in contact with side and top surfaces of the bank 148.

Additionally, in the contact area CA, the light-emitting layer 144 can be in contact with top and side surfaces of the overcoat layer 119 and can be separated by the insulation patterns 120 having the reversely-inclined side surfaces. Accordingly, the light-emitting layer 144 can expose the third auxiliary electrode 176 formed on the side surface of the insulation pattern 120.

Meanwhile, the light-emitting layer 144 can also be provided in the transparent area TA. In the transparent area TA, the light-emitting layer 144 can be in contact with the top surface of the second passivation layer 117.

The light-emitting layer 144 can emit white light and can include at least one hole auxiliary layer, at least one light-emitting material layer, and at least one electron auxiliary layer constituting one light-emitting unit. The hole auxiliary layer can include at least one of a hole injection layer (HIL) and a hole transport layer (HTL). The electron auxiliary layer can include at least one of an electron injection layer (EIL) and an electron transport layer (ETL). As an example, the at least one hole auxiliary layer and/or the at least one electron auxiliary layer may be omitted depending on the design.

The light-emitting layer 144 can have a stack structure in which two or more light-emitting units emitting light of different colors are stacked, and a charge generation layer (CGL) can be provided between two light-emitting units, without being limited thereto.

The second electrode 146 of a conductive material (e.g., a conductive material with relatively low work function) can be provided on the light-emitting layer 144. The second electrode 146 can be disposed over substantially the entire surface of the substrate 100.

The second electrode 146 can be formed of aluminum (Al), magnesium (Mg), silver (Ag), or an alloy thereof. In this case, the second electrode 146 can have a relatively thin thickness such that light from the light-emitting layer 144 can be transmitted therethrough. For example, the second electrode 146 can have a thickness of 5 nm to 10 nm, but embodiments of the present disclosure are not limited thereto.

Alternatively, the second electrode 146 can be formed of a transparent conductive material such as IGO or IZO.

The second electrode 146 can be in contact with a top surface of the light-emitting layer 144. In the contact area CA, the second electrode 146 may not be separated by the insulation patterns 120. The second electrode 146 can be provided along the top and side surfaces of the insulation pattern 120 and be in contact with the third auxiliary electrode 176 exposed on the side surface of the insulation pattern 120. This will be described in detail later.

The first electrode 142, the light-emitting layer 144, and the second electrode 146 of the emission area EA can constitute the light-emitting diode De. Here, the first electrode 142 can serve as an anode, and the second electrode 146 can serve as a cathode. However, embodiments of the present disclosure are not limited thereto.

Meanwhile, a capping layer and an encapsulation layer can be sequentially formed on the second electrode 146 and disposed over substantially the entire surface of the substrate 100.

As such, in another electroluminescent display device according to the embodiment of the present disclosure, each sub-pixel can include the emission area EA and the transparent area TA, so that the surrounding environment information such as backgrounds can be shown together through the transparent area TA while displaying a color image through the emission area EA.

In addition, by forming the insulation patterns 120 having the reversely-inclined side surfaces in the contact area CA, the light-emitting layer 144 can be separated, and the second electrode 146 can be in direct contact with the third auxiliary electrode 176 on the side surface of the insulation pattern 120, so that the contact properties between the second electrode 146 and the first, second, and third auxiliary electrodes 172, 174, and 176 can be increased. Accordingly, a difference in resistance of the second electrode 146 can be reduced or prevented, so that the luminance of the electroluminescent display device can be made uniform.

The configuration of the contact area according to embodiments of the present disclosure will be described in more detail with reference to accompanying drawings.

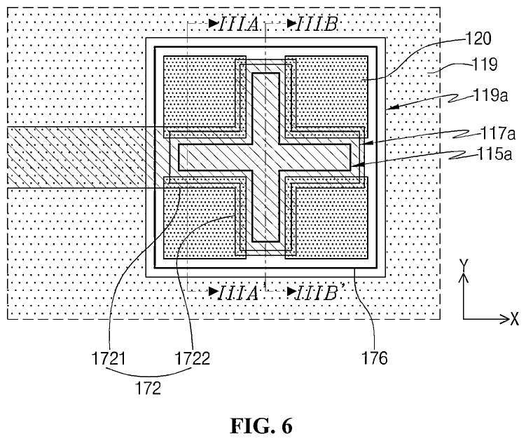

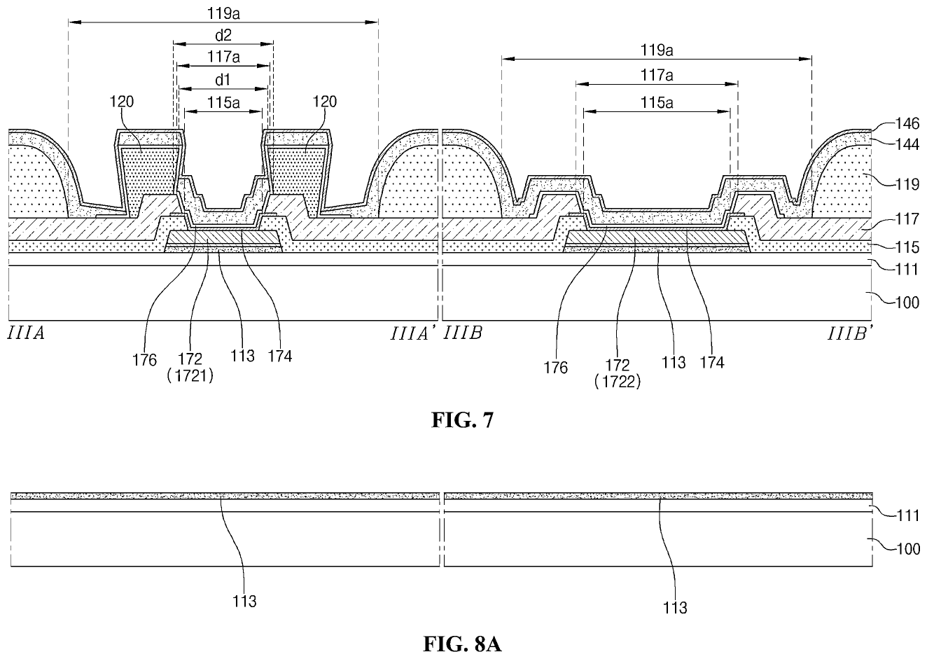

FIG. 6 is a schematic plan view of a contact area of an electroluminescent display device according to a first embodiment of the present disclosure, and FIG. 7 is a cross-sectional view corresponding to line IIIA-IIIA′ and line IIIB-IIIB′ of FIG. 6.

As shown in FIG. 6 and FIG. 7, in the electroluminescent display device according to the first embodiment of the present disclosure, the first and second auxiliary electrodes 172 and 174 can be provided to have a shape with a plurality of L-like sides in plan, and the plurality of insulation patterns 120 having the reversely-inclined side surfaces and the third auxiliary electrode 176 covering the insulation patterns 120 can be provided on the first and second auxiliary electrodes 172 and 174. Therefore, the light-emitting layer 144 can be separated by the reversely-inclined side surface of each insulation pattern 120, so that the second electrode 146 can be in direct contact with the third auxiliary electrode 176 on all side surfaces of each insulation pattern 120.

Specifically, the buffer layer 111 can be provided on the substrate 100. The gate insulation layer 113 and the first auxiliary electrode 172 can be sequentially provided on the buffer layer 111.

The first auxiliary electrode 172 can include a first portion 1721 extending in the first direction, which is the X direction, and a second portion 1722 extending in the second direction, which is the Y direction. The first portion 1721 and the second portion 1722 can be connected to each other and be provided as one body. The first portion 1721 and the second portion 1722 can substantially cross each other to thereby form the plurality of L-like sides in plan. For example, the first auxiliary electrode 172 can have four L-like sides. The first auxiliary electrode 172 can have a cross shape in plan.

In addition, the gate insulation layer 113 can have the same or substantially the same shape as the first auxiliary electrode 172. For example, the gate insulation layer 113 can have a cross shape in plan.

The first passivation layer 115 can be provided on the first auxiliary electrode 172. The first passivation layer 115 can have a first contact hole 115a exposing a top surface of the first auxiliary electrode 172. The first contact hole 115a can have substantially the same shape as the first auxiliary electrode 172, and the first contact hole 115a can have a cross shape in plan. In this case, the area of the first contact hole 115a can be smaller than the area of the first auxiliary electrode 172. Accordingly, the width and length of the first contact hole 115a can be smaller than the width and length of the first auxiliary electrode 172.

The second auxiliary electrode 174 can be provided on the first passivation layer 115. The second auxiliary electrode 174 can be in contact with the first auxiliary electrode 172 exposed through the first contact hole 115a. The second auxiliary electrode 174 can have substantially the same shape as the first auxiliary electrode 172. Accordingly, the second auxiliary electrode 174 can have a cross shape in plan, and the width and length of the second auxiliary electrode 174 can be greater than the width and length of the first contact hole 115a. As an example, the width and length of the second auxiliary electrode 174 can be greater than, equal to or smaller than the width and length of the first auxiliary electrode 172. As an example, the second auxiliary electrode 174 may overlap the entirety of the first contact hole 115a. As an example, the second auxiliary electrode 174 may have a shape (such as a rectangular shape, a square shape, a circular shape, etc.) different from the shape of the first auxiliary electrode 172, while overlapping the entirety of the first contact hole 115a. As an example, the first auxiliary electrode 172 may overlap the entirety of the first contact hole 115a. As an example, the first auxiliary electrode 172 may have a shape (such as a rectangular shape, a square shape, a circular shape, etc.) different from the shape of the first contact hole 115a, while overlapping the entirety of the first contact hole 115a.

The second auxiliary electrode 174 can be omitted.

The second passivation layer 117 can be provided on the second auxiliary electrode 174. The second passivation layer 117 can have a second contact hole 117a exposing the second auxiliary electrode 174. The second contact hole 117a can have substantially the same shape as the first and second auxiliary electrodes 172 and 174, and the second contact hole 117a can have a cross shape in plan. In this case, the area of the second contact hole 117a can be smaller than the area of the second auxiliary electrode 174. Accordingly, the width and length of the second contact hole 117a can be smaller than the width and length of the first auxiliary electrodes 172 and/or second auxiliary electrodes 174.

In addition, the second contact hole 117a can have a larger area than the first contact hole 115a, and the first contact hole 115a can be disposed in the second contact hole 117a. Alternatively, the second contact hole 117a can have substantially the same area as the first contact hole 115a. Embodiments are not limited thereto. As an example, the second contact hole 117a can have substantially the same shape as the first contact hole 115a, while having a shape different from the shape of the first auxiliary electrode 172 and the second auxiliary electrode 174. As an example, the width and length of the second contact hole 117a can be greater than, equal to or smaller than the width and length of the first contact hole 115a. As an example, the entirety of the second contact hole 117a may overlap the second auxiliary electrode 174. As an example, the second contact hole 117a may overlap the entirety of first contact hole 115a.

The plurality of insulation patterns 120 can be provided on the second passivation layer 117. The plurality of insulation patterns 120 can be spaced apart from each other and be disposed to correspond to and overlap the L-like sides of the first auxiliary electrode 172, respectively. For example, four insulation patterns 120 can be correspond to and overlap the four L-like sides of the first auxiliary electrode 172, respectively.

In addition, each insulation pattern 120 can correspond to and overlap each L-like side of the second auxiliary electrode 174, and the second auxiliary electrode 174 can be exposed between adjacent insulation patterns 120.

Each insulation pattern 120 can have the reversely-inclined side surfaces. For example, the side surface of the insulation pattern 120 can have an angle greater than 90 degrees with respect to the top surface of the substrate 100. The width of the insulation pattern 120 can increase from the bottom side of the insulation pattern 120 contacting the second passivation layer 117 to the top side of the insulation pattern 120 far from the second passivation layer 117, and the width of the top side of the insulation pattern 120 can be wider than the width of the bottom side of the insulation pattern 120. Accordingly, a first distance dl between the top sides of adjacent insulation patterns 120 can be smaller than a second distance d2 between the bottom sides of the adjacent insulation patterns 120.

In this case, the first distance d1 can be smaller than the width of the second contact hole 117a, and the second distance d2 can be greater than the width of the second contact hole 117a. For example, the width of the second contact hole 117a can be greater than the first distance d1 and smaller than the second distance d2. In addition, the first distance d1 can be greater than the width of the first contact hole 115a.

The third auxiliary electrode 176 can be disposed on the plurality of insulation patterns 120. The third auxiliary electrode 176 can cover the plurality of insulation patterns 120. The third auxiliary electrode 176 can be formed through a sputtering method with relatively high step coverage characteristics, without being limited thereto. Accordingly, the third auxiliary electrode 176 can be formed not only on the top surface of each insulation pattern 120 but also on the side surface of the insulation pattern 120 and be in contact with the side and top surfaces of the insulation pattern 120.

In addition, the third auxiliary electrode can cover the first and second auxiliary electrodes 172 and 174 and be in contact with the second auxiliary electrode 174 exposed through the second contact hole 117a between adjacent insulation patterns 120. The third auxiliary electrode 176 can also be in contact with the side and top surfaces of the second passivation layer 117.

Meanwhile, the overcoat layer 119 can be provided on the second passivation layer 117. The overcoat layer 119 can have the opening 119a corresponding to the first, second, and third auxiliary electrodes 172, 174, and 176.

The first, second, and third auxiliary electrodes 172, 174, and 176 can be disposed substantially in the opening 119a, and the second and third auxiliary electrodes 174 and 176 can be spaced apart from the overcoat layer 119, e.g., in a lateral direction. Accordingly, the top surface of the second passivation layer 117 can be exposed between the third auxiliary electrode 176 and the overcoat layer 119.

However, embodiments of the present disclosure are not limited thereto. In other embodiments, the third auxiliary electrode 176 can overlap and be in contact with the overcoat layer 119. In this case, the third auxiliary electrode 176 can be disposed on the overcoat layer 119. Alternatively, the third auxiliary electrode 176 can be disposed between the second passivation layer 117 and the overcoat layer 119.

In addition, the first and second contact holes 115a and 117a and the plurality of insulation patterns 120 can also be disposed in the opening 119a and be spaced apart from the overcoat layer 119.

The side surface of the overcoat layer 119 can have substantially normal inclination. For example, the side surface of the overcoat layer 119 can have an angle smaller than 90 degrees with respect to the top surface of the substrate 100.

The light-emitting layer 144 and the second electrode 146 can be sequentially provided on the overcoat layer 119 and the third auxiliary electrode 176. The light-emitting layer 144 and the second electrode 146 can be formed over substantially the entire surface of the substrate 100. The light-emitting layer 144 and the second electrode 146 can cover the top and side surfaces of the overcoat layer 119, and the light-emitting layer 144 can be in contact with the top and side surfaces of the overcoat layer 119.

The light-emitting layer 144 can be formed through a thermal evaporation method with relatively low step coverage characteristics, without being limited thereto. Accordingly, the light-emitting layer 144 may not be formed on the reversely-inclined side surface of the insulation pattern 120, and the light-emitting layer 144 can be separated by the insulation pattern 120. For example, a portion of the light-emitting layer 144 on the insulation pattern 120 can be separated from a portion of the light-emitting layer 144 between adjacent insulation patterns 120 and a portion of the light-emitting layer 144 between the insulation pattern 120 and the overcoat layer 119, thereby exposing the third auxiliary electrode 176 formed on the side surface of the insulation pattern 120.

In this case, the thickness of the light-emitting layer 144 can become thinner toward the side surface of the insulation pattern 120 between the insulation pattern 120 and the overcoat layer 119. In addition, the light-emitting layer 114 can be in contact with the top surface of the second passivation layer 117 between the insulation pattern 120 and the overcoat layer 119.

On the other hand, the second electrode 146 can be formed through a sputtering method with relatively high step coverage characteristics, without being limited thereto. The second electrode 146 may not be separated by the insulation patterns 120 and can be formed along the top and side surfaces of the insulation patterns 120.

Accordingly, the second electrode 146 can be in contact with the third auxiliary electrode 176 on the side surface of the insulation pattern 120 and can be electrically connected to the first and second auxiliary electrodes 172 and 174 through the third auxiliary electrode 176. In this case, the second electrode 146 can be in contact with the third auxiliary electrode 176 on all side surfaces of the insulation pattern 120. Specifically, the second electrode 146 can be in contact with the third auxiliary electrode 176 both on inner side surfaces of the insulation pattern 120, for example, side surfaces facing another insulation pattern 120 and on outer side surfaces of the insulation pattern 120, for example, side surfaces facing the overcoat layer 119, and the contact area between the second electrode 146 and the third auxiliary electrode 176 can increase. Accordingly, the contact properties between the second electrode 146 and the third auxiliary electrode 176 can be improved.

As such, in the electroluminescent display device according to the first embodiment of the present disclosure, the light-emitting layer 144 can be separated by the insulation pattern 120 having the reversely-inclined side surfaces over the first and second auxiliary electrodes 172 and 174, and the second electrode 146 can be in contact with the third auxiliary electrode 176 on all side surfaces of the insulation pattern 120, so that the contact area between the second electrode 146 and the third auxiliary electrode 176 can increase to thereby improve the contact properties between the second electrode 146 and the third auxiliary electrode 176.

In addition, the first and second auxiliary electrodes 172 and 174 can be configured to have the cross shape with the plurality of L-like sides, and the plurality of insulation pattern 120 can be provided to correspond to the plurality of L-like sides, respectively, thereby further increasing the contact area between the second electrode 146 and the third auxiliary electrode 176.

Here, it is shown that the opening 119a and the third auxiliary electrode 176 have a square shape in plan and each of the first and second auxiliary electrodes 172 and 174 and the first and second contact holes 115a and 117a has substantially the same length in the first direction and the second direction. However, embodiments of the present disclosure are not limited thereto. In other embodiments, the opening 119a and the third auxiliary electrode 176 can have a rectangular shape in plan, and each of the first and second auxiliary electrodes 172 and 174 and the first and second contact holes 115a and 117a can have different lengths in the first direction and the second direction. As an example, the opening 119a and the third auxiliary electrode 176 can have the same shape or different shapes. Although it is illustrated that each of first and second auxiliary electrodes 172 and 174 and the first and second contact holes 115a and 117a have four L-like sides, and there are four insulation patterns 120, embodiments are not limited thereto. As an example, each of or at least one of the first and second auxiliary electrodes 172 and 174 and the first and second contact holes 115a and 117a may have three L-like sides or five or more L-like sides, and there may be three insulation patterns or five or more insulation patterns, each of which may have reversely-inclined side surfaces.

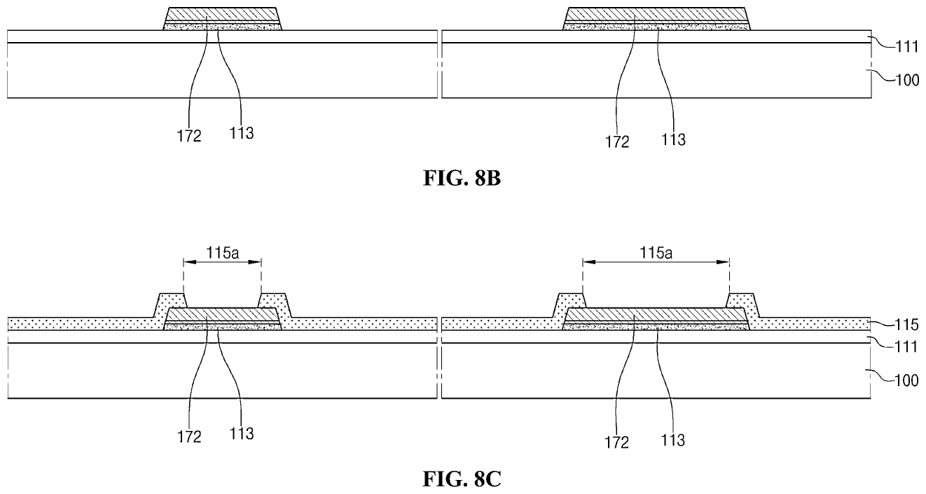

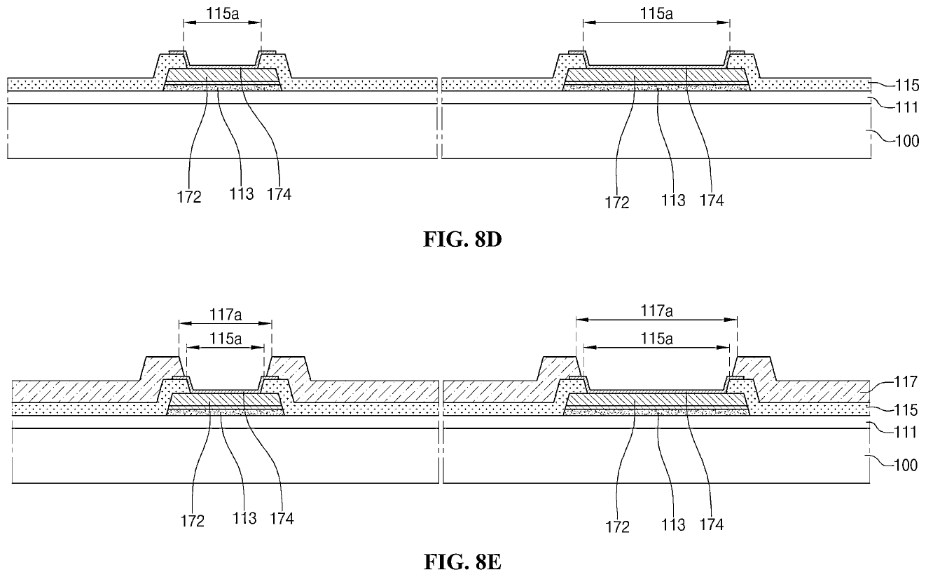

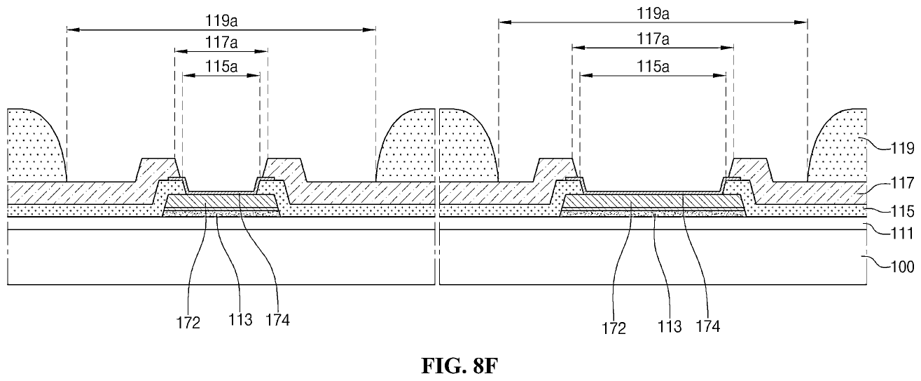

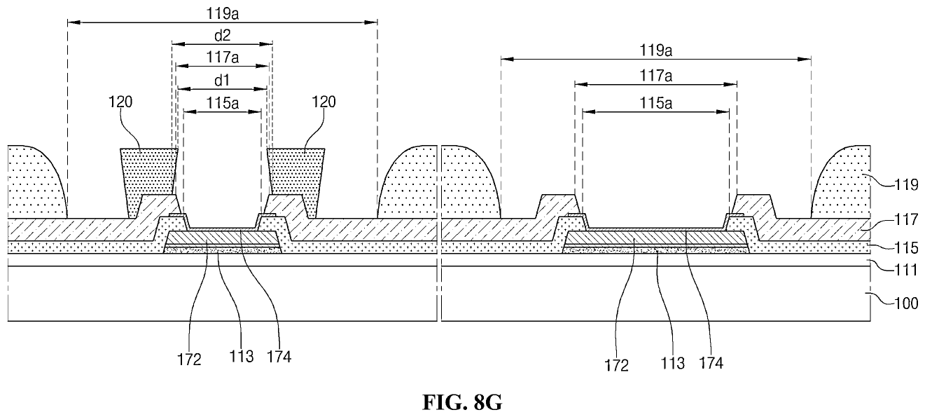

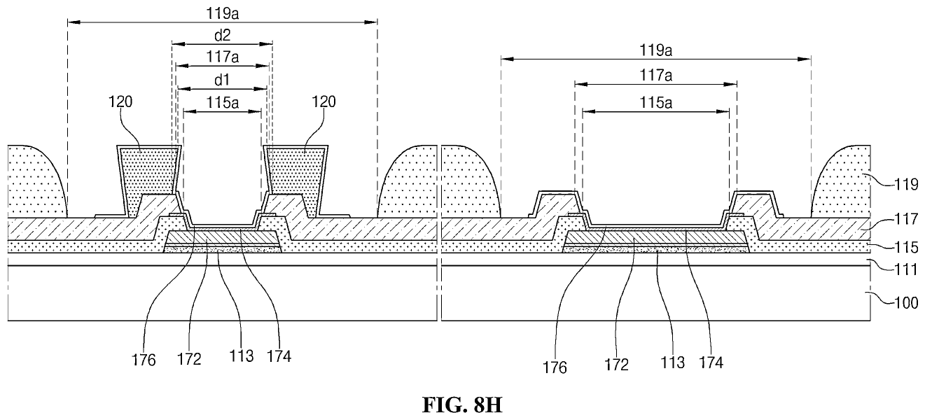

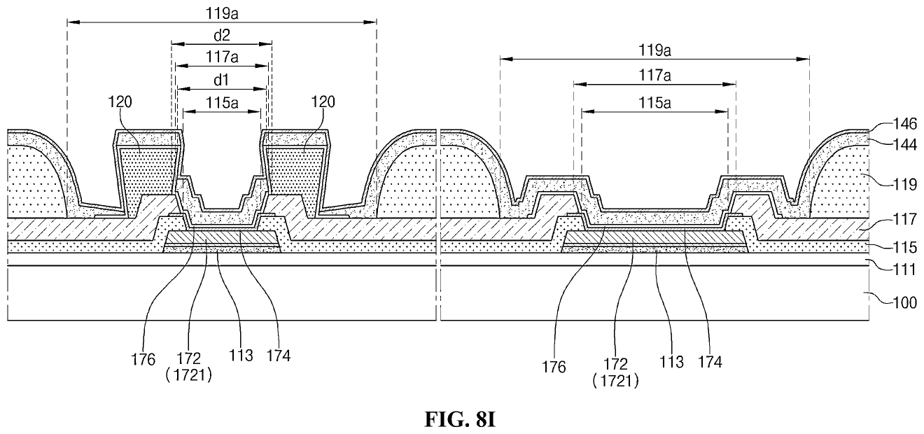

A method of manufacturing the electroluminescent display device according to the first embodiment of the present disclosure will be described in detail with reference to FIGS. 8A to 8I.

FIGS. 8A to 8I are schematic cross-sectional views of a contact area in steps of manufacturing an electroluminescent display device according to the first embodiment of the present disclosure, and will be described with reference to FIG. 5 together.

First, as shown in FIG. 5 and FIG. 8A, the light-blocking layer 152, the power line 162, the data line 166, and the first capacitor electrode 154 can be formed on the substrate 100 by depositing a conductive material and patterning it through a photolithography process. Then, the buffer layer 111 can be formed on the light-blocking layer 152, the power line 162, the data line 166, and the first capacitor electrode 154 by depositing an inorganic insulating material over substantially the entire surface of the substrate 100.

Here, the photolithography process can include steps of applying photoresist on a thin film to be patterned, light-exposing and developing the photoresist, etching the thin film, and stripping the photoresist. The etching step can be carried out through a wet etching process using etchant or a dry etching process using gases. When the thin film to be patterned is formed of a material having photosensitivity, only the light-exposing and developing steps can be performed without steps of applying the photoresist and etching the thin film.

Next, the first and second semiconductor layers 122 and 132 can be formed on the buffer layer 111 by depositing a semiconductor material and patterning it through a photolithography process, and the gate insulation layer 113 can be formed on the buffer layer 111 provided with the first and second semiconductor layers 122 and 132 thereon by depositing an inorganic insulating material over substantially the entire surface of the substrate 100.

Then, the contact holes exposing the first and second semiconductor layers 122 and 132 of FIG. 5 can be formed by patterning the gate insulation layer 113 through a photolithography process, and the contact holes respectively exposing the power line 162 and the light-blocking layer 152 of FIG. 5 can be formed by patterning the gate insulation layer 113 and the buffer layer 111 through the photolithography process.

Next, as shown in FIG. 5 and FIG. 8B, the first auxiliary electrode 172 can be formed on the gate insulation layer 113 by depositing a conductive material and patterning it through a photolithography process. At this time, the gate insulation layer 113 can also be patterned to have the same shape as the first auxiliary electrode 172, without being limited thereto. As an example, the gate insulation layer 113 may not be patterned to have the same shape as the first auxiliary electrode 172. As an example, the gate insulation layer 113 may be patterned to have a different shape as the first auxiliary electrode 172.

Here, the first auxiliary electrode 172 and the gate insulation layer 113 can be patterned by a dry etching process. Alternatively, the first auxiliary electrode 172 can be patterned by a wet etching process, and the gate insulation layer 113 can be patterned by a dry etching process. However, embodiments of the present disclosure are not limited thereto.

Meanwhile, the first gate electrode 124, the first source electrode 126, the first drain electrode 128, the second source/drain electrode 137, and the second capacitor electrode 156 of FIG. 5 can also be formed together with the first auxiliary electrode 172, for example, during the same process, without being limited thereto.

Next, as shown in FIG. 5 and FIG. 8C, the first passivation layer 115 can be formed on the first auxiliary electrode 172 by depositing an inorganic insulating material, and the first contact hole 115a exposing the first auxiliary electrode 172 can be formed by patterning the first passivation layer 115 through a photolithography process. At this time, the contact hole exposing the first source electrode 126 of FIG. 5 can also be formed together with the first contact hole 115a, for example, during the same process, without being limited thereto.

Next, as shown in FIG. 5 and FIG. 8D, the second auxiliary electrode 174 can be formed on the first passivation layer 115 by depositing a conductive material and patterning it through a photolithography process. At this time, the connection electrode 184 of FIG. 5 can also be formed together with the second auxiliary electrode 174, for example, during the same process, without being limited thereto.

The second auxiliary electrode 174 can overlap the first auxiliary electrode 172 and be in contact with the first auxiliary electrode 172 through the first contact hole 115a.

Next, as shown in FIG. 5 and FIG. 8E, the second passivation layer 117 can be formed on the second auxiliary electrode 174 by depositing an inorganic insulating material, and the second contact hole 117a exposing the second auxiliary electrode 174 can be formed by patterning the second passivation layer 117 through a photolithography process.

Next, as shown in FIG. 5 and FIG. 8F, the overcoat layer 119 can be formed on the second passivation layer 117 by applying an organic insulating material, and the opening 119a can be formed to correspond to the first and second auxiliary electrodes 172 and 174 by patterning the overcoat layer 119 through a photolithography process.

The opening 119a can have a substantially greater area than the first and second auxiliary electrodes 172 and 174. The first and second auxiliary electrodes 172 and 174 can be substantially disposed in the opening 119a and be substantially spaced apart from the overcoat layer 119, e.g., in a lateral direction.

In addition, the opening 119a can have a greater area than the first and second contact holes 115a and 117a. The first and second contact holes 115a and 117a can be disposed in the opening 119a and be spaced apart from the overcoat layer 119, e.g., in a lateral direction.

Here, the overcoat layer 119 can be formed of a material having negative photosensitivity in which a portion exposed to light remains after developing. However, embodiments of the present disclosure are not limited thereto. In other embodiments, the overcoat layer 119 can be formed of a material having positive photosensitivity in which a portion exposed to light is removed after developing, or can be formed of a material having no photosensitivity.

Meanwhile, when the opening 119a is formed, the overcoat layer 119 corresponding to the transparent area TA of FIG. 5 can also be removed together.

In addition, the contact hole exposing the connection electrode 186 can also be formed together with the opening 119a. At this time, the second passivation layer 117 corresponding to the contact hole exposing the connection electrode 186 can be removed in the step of forming the opening 119a or in the step of forming the second contact hole 117a.

Next, as shown in FIG. 5 and FIG. 8G, the plurality of insulation patterns 120 can be formed in the opening 119a by applying an organic insulating material on the overcoat layer 119 having the opening 119a and patterning it through a photolithography process.

The plurality of insulation patterns 120 can be spaced apart from each other and also be spaced apart from the overcoat layer 119. Each insulation pattern 120 can have the reversely-inclined side surfaces. Accordingly, the top side of each insulation pattern 120 can have a wider width than the bottom side, and the first distance dl between the top sides of adjacent insulation patterns 120 can be smaller than the second distance d2 between the bottom sides of adjacent insulation patterns 120.

The insulation patterns 120 can be formed of a different material from the overcoat layer 119. Alternatively, the insulation patterns 120 can be formed of the same material as the overcoat layer 119. In this case, the reversely-inclined side surfaces of the insulation patterns 120 can be formed by varying the process conditions, such as light-exposing and/or curing conditions, when forming the overcoat layer 119, without being limited thereto.

In addition, the height of the insulation patterns 120 can be the same as the height of the overcoat layer 119. Alternatively, the height of the insulation patterns 120 can be different from the height of the overcoat layer 119. For example, the height of the insulation patterns 120 can be greater than, equal to or smaller than the height of the overcoat layer 119. For example, the height of the insulation patterns 120 can be 0.5 to 1.5 times the height of the overcoat layer 119.

Meanwhile, it is described that the insulation patterns 120 are formed after forming the overcoat layer 119, but embodiments of the present disclosure are not limited thereto. In other embodiments, the overcoat layer 119 can be formed after forming the insulation patterns 120, or even formed together with the insulation patterns 120 during the same process.

Next, as shown in FIG. 5 and FIG. 8H, the third auxiliary electrode 176 can be formed on the plurality of insulation patterns 120 by depositing a conductive material and patterning it through a photolithography process. The third auxiliary electrode 176 can cover the plurality of insulation patterns 120 and can be in contact with the second auxiliary electrode 174 exposed through the second contact hole 117a between adjacent insulation patterns 120.

In addition, the third auxiliary electrode 176 can be in contact with the side and top surfaces of each insulation pattern 120 and the side and top surfaces of the second passivation layer 117. The third auxiliary electrode 176 can be spaced apart from the overcoat layer 119, e.g., in a lateral direction.

Then, the first electrode 142 and the bank 148 of FIG. 5 can be formed on the overcoat layer 119.

Meanwhile, the third auxiliary electrode 176 can be formed of the same material and through the same process as the first electrode 142 of FIG. 5. In this case, the first electrode 142 can have a multiple-layered structure, and the third auxiliary electrode 176 can have a single-layered structure, without being limited thereto. As an example, the first electrode 142 and the third auxiliary electrode 176 can have the same structure. As an example, the first electrode 142 and the third auxiliary electrode 176 may have the multiple-layered structure or the single-layered structure.

Next, as shown in FIG. 5 and FIG. 8I, the light-emitting layer 144 and the second electrode 146 can be sequentially formed on the first electrode 142, the bank 148, the overcoat layer 119, and the third auxiliary electrode 176. In this case, the light-emitting layer 144 and the second electrode 146 can be formed over substantially the entire surface of the substrate 100 through a vacuum evaporation method and a sputtering method, respectively.

The light-emitting layer 144 can be separated by the insulation patterns 120 having the reversely-inclined side surfaces to thereby expose the third auxiliary electrode 176 formed on the side surfaces of the insulation patterns 120. On the other hand, the second electrode 146 can be formed and connected along the top and side surfaces of the insulation patterns 120 without separation and can be in contact with the third auxiliary electrode 176 exposed on the side surfaces of the insulation patterns 120.

Accordingly, the second electrode 146 can be electrically connected to the first and second auxiliary electrodes 172 and 174 through the third auxiliary electrode 176 and be electrically connected to the power line 162 of FIG. 5 through the first and second auxiliary electrodes 172 and 174.

The electroluminescent display device manufactured by the above method can be subjected to various tests including a lighting test, to determine whether there are any defects. At this time, if the contact between the second electrode 146 and the third auxiliary electrode 176 is unstable during the lighting test, a part with low brightness can occur locally. Accordingly, by repairing the part with low brightness using a laser, the second electrode 146 can be directly connected to the first auxiliary electrode 172.

In this case, the location and area for repairing can vary depending on the size of the laser beam, and this will be explained with reference to FIGS. 9 to 12.

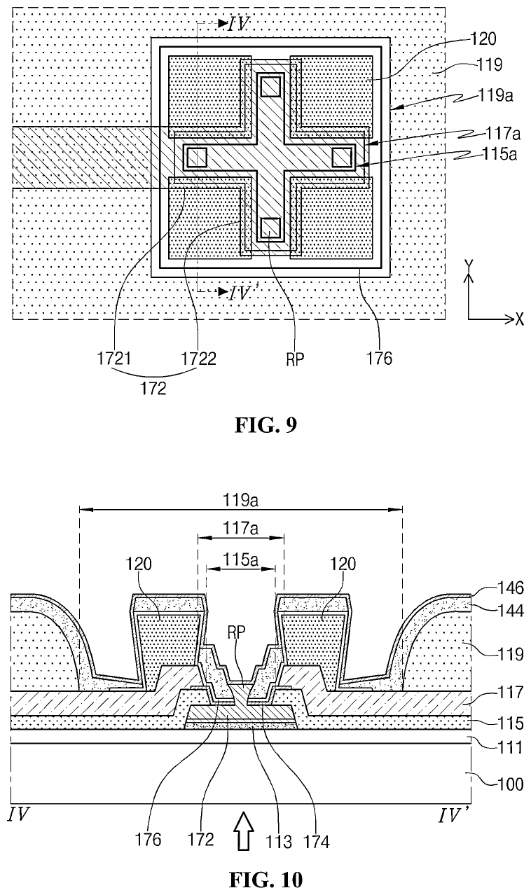

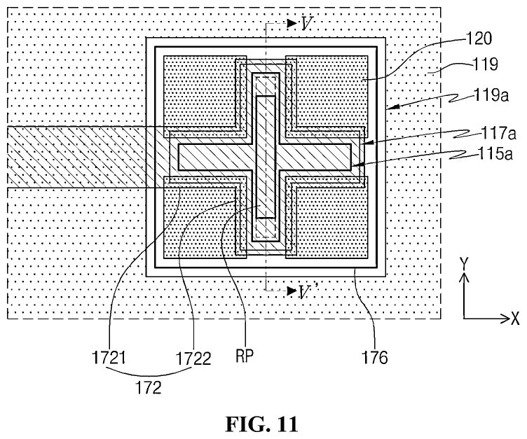

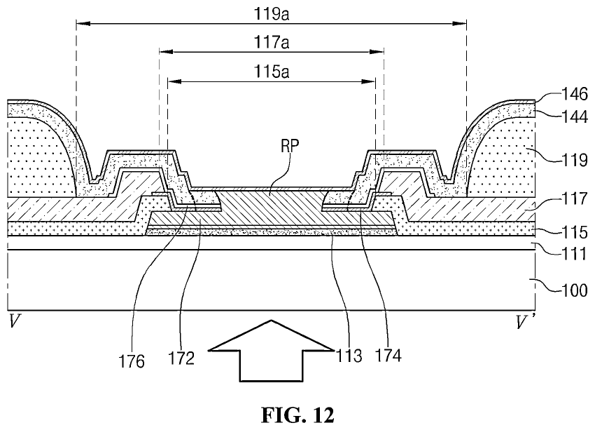

FIG. 9 is a schematic plan view of a contact area of an electroluminescent display device repaired according to an embodiment of the present disclosure, FIG. 10 is a cross-sectional view corresponding to line IV-IV′ of FIG. 9, FIG. 11 is a schematic plan view of a contact area of an electroluminescent display device repaired according to another embodiment of the present disclosure, and FIG. 12 is a cross-sectional view corresponding to line V-V′ of FIG. 11. Here, the size of the laser beam used in repairing of FIGS. 11 and 12 can be greater than the size of the laser beam used in repairing of FIGS. 9 and 10.

As shown in FIGS. 9 to 12, a laser beam under the substrate 100 can be irradiated to the first auxiliary electrode 172 for the part with low brightness detected during the lighting test process, and a portion of the first auxiliary electrode 172 exposed to the laser beam can protrude upward and can be in contact with the second electrode 146. As an example, a portion of the first auxiliary electrode 172 exposed to the laser beam can protrude upward and can be in contact with the second electrode 146 by passing through the second auxiliary electrode 174, the third auxiliary electrode 176 and light-emitting layer 144. As an example, the portion of the first auxiliary electrode 172 exposed to the laser beam and protruding upward may have a flat bottom portion, without being limited thereto.

In this case, as shown in FIG. 9 and FIG. 10, when the size of the laser beam is relatively small, the repair point RP can correspond to substantially each end of the first auxiliary electrode 172 and can have a dot shape, without being limited thereto. As an example, the repair point RP can correspond to a portion other than each end of the first auxiliary electrode 172.

On the other hand, as shown in FIG. 11 and FIG. 12, when the size of the laser beam is relatively large, the repair point RP can extend substantially along the first auxiliary electrode 172 and can have a line shape. At this time, the repair point RP can have a length corresponding to the solid line or a length corresponding to the dotted line depending on the size and/or intensity of the laser beam.

Meanwhile, as shown in FIG. 11, the repair point RP is shown as extending along the second portion 1722 of the first auxiliary electrode 172. However, the repair point RP can extend along the first portion 1721 of the first auxiliary electrode 172.

As such, even though the contact between the second electrode 146 and the third auxiliary electrode 176 is unstable, the electrical connection between the second electrode 146 and the first auxiliary electrode 172 can be improved by repairing using the laser.

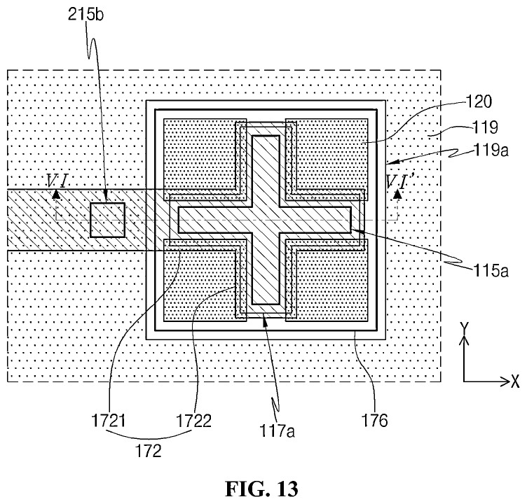

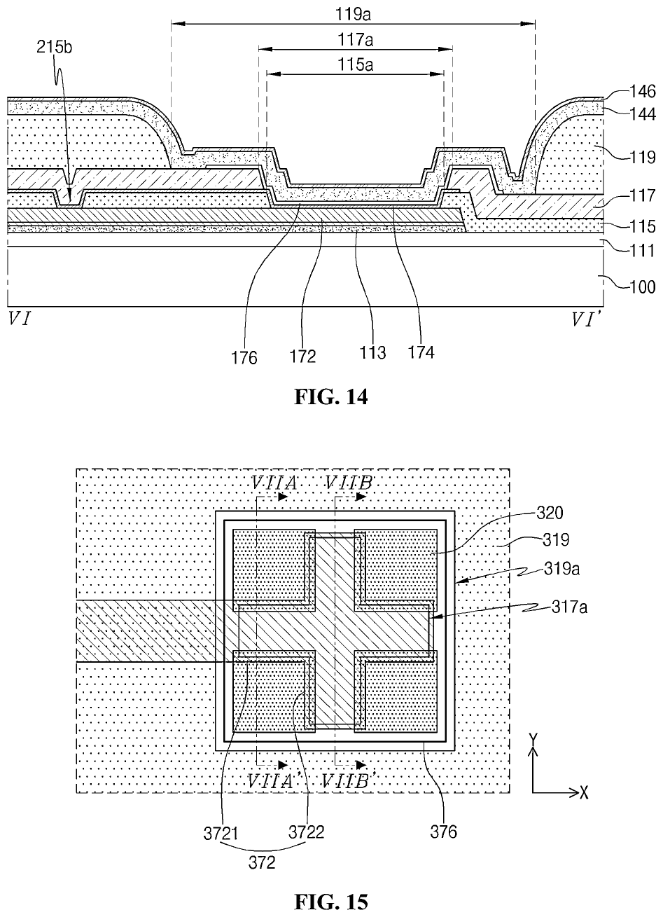

FIG. 13 is a schematic plan view of a contact area of an electroluminescent display device according to a second embodiment of the present disclosure, and FIG. 14 is a cross-sectional view corresponding to line VI-VI′ of FIG. 13. The electroluminescent display device according to the second embodiment of the present disclosure has substantially the same configuration as that of the first embodiment, except for an auxiliary contact hole. The same parts as those of the first embodiment are designated by the same reference signs/numerals, and explanation for the same parts can be shortened or omitted.

As shown in FIG. 13 and FIG. 14, in the electroluminescent display device according to the second embodiment of the present disclosure, the first passivation layer 115 can have the first contact hole 115a and an auxiliary contact hole 215b exposing the first auxiliary electrode 172, and the second auxiliary electrode 174 can be in contact with the first auxiliary electrode 172 through the first contact hole 115a and the auxiliary contact hole 215b.

Specifically, the buffer layer 111 can be provided on the substrate 100. The gate insulation layer 113 and the first auxiliary electrode 172 can be sequentially provided on the buffer layer 111, and the first passivation layer 115 can be provided on the first auxiliary electrode 172.

The first auxiliary electrode 172 can include the first portion 1721 extending in the first direction, which is the X direction, and the second portion 1722 extending in the second direction, which is the Y direction. The first auxiliary electrode 172 can have a cross shape in plan.

The first passivation layer 115 can have the first contact hole 115a and the auxiliary contact hole 215b exposing the top surface of the first auxiliary electrode 172. The auxiliary contact hole 215b can be spaced apart from the first contact hole 115a in the first direction, and the auxiliary contact hole 215b can be disposed substantially over the first portion 1721 of the first auxiliary electrode 172.

The first contact hole 115a can have a cross shape in plan, and the auxiliary contact hole 215b can have a rectangular shape. Alternatively, the auxiliary contact hole 215b can have a polygonal, circular, or elliptical shape other than the rectangular shape, without being limited thereto.

The second auxiliary electrode 174 can be provided on the first passivation layer 115. The second auxiliary electrode 174 can be in contact with the top surface of the first auxiliary electrode 172 exposed through the first contact hole 115a and the auxiliary contact hole 215b.

The second passivation layer 117 can be provided on the second auxiliary electrode 174. The second passivation layer 117 can have the second contact hole 117a exposing the second auxiliary electrode 174. The second contact hole 117a can be spaced apart from the auxiliary contact hole 215b.

The overcoat layer 119 can be provided on the second passivation layer 117. The overcoat layer 119 can have a substantially flat top surface and have the opening 119a corresponding to the first and second contact holes 115a and 117a. The overcoat layer 119 can be spaced apart from the first and second contact holes 115a and 117a and overlap the auxiliary contact hole 215b.

The plurality of insulation patterns 120 with the reversely-inclined side surfaces and the third auxiliary electrode 176 can be provided in the opening 119a on the second passivation layer 117. The third auxiliary electrode 176 can cover the plurality of insulation patterns 120 and be in contact with the second auxiliary electrode 174 through the second contact hole 117a. The plurality of insulation patterns 120 and the third auxiliary electrode 176 can be spaced apart from the overcoat layer 119 and also be spaced apart from the auxiliary contact hole 215b.

The light-emitting layer 144 and the second electrode 146 can be sequentially provided on the overcoat layer 119.

As such, in the electroluminescent display device according to the second embodiment of the present disclosure, the second auxiliary electrode 174 can be in contact with the first auxiliary electrode 172 through the first contact hole 115a and the auxiliary contact hole 215b. Accordingly, the contact properties between the first auxiliary electrode 172 and the second auxiliary electrode 174 can be improved in comparison with the first embodiment.

The electroluminescent display device according to the second embodiment of the present disclosure can be manufactured by substantially the same method as the electroluminescent display device according to the first embodiment shown in FIGS. 8A to 8I, and in the step of FIG. 8C, the auxiliary contact hole 215b can be formed together when the first contact hole 115a is formed.

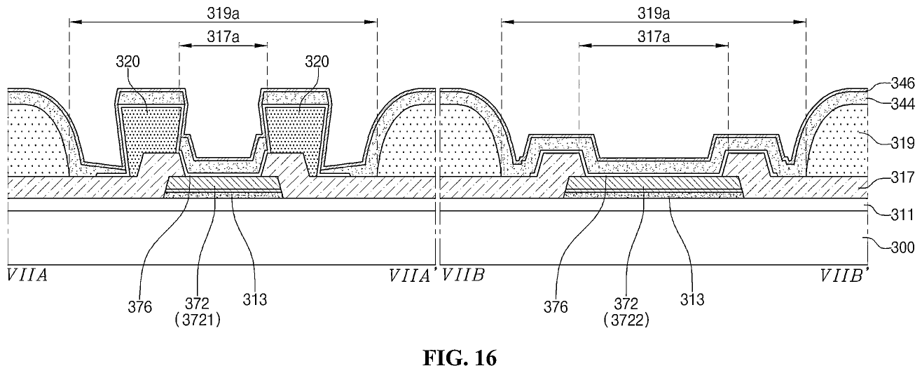

FIG. 15 is a schematic plan view of a contact area of an electroluminescent display device according to a third embodiment of the present disclosure, and FIG. 16 is a cross-sectional view corresponding to line VIIA-VIIA′ and line VIIB-VIIB′ of FIG. 15. The electroluminescent display device according to the third embodiment of the present disclosure has substantially the same configuration as that of the first embodiment, except for the auxiliary electrode. The same parts as those of the first embodiment are designated by the same or similar reference signs/numerals, and explanation for the same parts can be shortened or omitted.

As shown in FIG. 15 and FIG. 16, in the electroluminescent display device according to the third embodiment of the present disclosure, the buffer layer 311 can be provided on the substrate 300, and the gate insulation layer 313 and the first auxiliary electrode 372 can be sequentially provided on the buffer layer 311. The first auxiliary electrode 372 can include a first portion 3721 extending in the first direction, which is the X direction, and a second portion 3722 extending in the second direction, which is the Y direction. The first portion 3721 and the second portion 3722 can be connected to each other and be provided as one body. The first auxiliary electrode 372 can have a cross shape with a plurality of L-like sides in plan.

A passivation layer 317 can be provided on the first auxiliary electrode 372. The passivation layer 317 can be a protection layer. The passivation layer 317 can have a contact hole 317a exposing the top surface of the first auxiliary electrode 372.

The contact hole 317a can have substantially the same shape as the first auxiliary electrode 372 and can have a cross shape in plan. In this case, the area of the contact hole 317a can be smaller than the area of the first auxiliary electrode 372. Accordingly, the width and length of the contact hole 317a can be smaller than the width and length of the first auxiliary electrode 372.

The plurality of insulation patterns 320 can be provided on the passivation layer 317. The plurality of insulation patterns 320 can be spaced apart from each other and be disposed to correspond to and overlap the L-like sides of the first auxiliary electrode 372, respectively.

Each insulation pattern 320 can have the reversely-inclined side surfaces, and the width of the top side of the insulation pattern 320 can be wider than the width of the bottom side of the insulation pattern 320. Accordingly, the distance between the top sides of adjacent insulation patterns 320 can be smaller than the distance between the bottom sides of adjacent insulation patterns 320. In addition, the distance between the top sides of adjacent insulation patterns 320 can be smaller than the width of the contact hole 317a, and the distance between the bottom sides of adjacent insulation patterns 320 can be greater than the width of the contact hole 317a.

The second auxiliary electrode 376 can be disposed on the plurality of insulation patterns 320. The second auxiliary electrode 376 can cover the plurality of insulation patterns 320. The second auxiliary electrode 376 can be formed not only on the top surface of each insulation pattern 320 but also on the side surface of each insulation pattern 320 and can be in contact with the top and side surfaces of each insulation pattern 320.

Further, the second auxiliary electrode 376 can cover the first auxiliary electrode 372 and can be in contact with the first auxiliary electrode 372 exposed through the contact hole 317a between adjacent insulation patterns 320. The second auxiliary electrode 376 can also be in contact with the top and side surfaces of the passivation layer 317.

Meanwhile, the overcoat layer 319 can be provided on the second passivation layer 317. The overcoat layer 319 can have a substantially flat top surface and have the opening 319a corresponding to the first and second auxiliary electrodes 372 and 376.

The first and second auxiliary electrodes 372 and 376 can be disposed substantially in the opening 319a, and the second auxiliary electrode 376 can be spaced apart from the overcoat layer 319, e.g., in a lateral direction. Accordingly, the top surface of the passivation layer 317 can be exposed between the second auxiliary electrode 376 and the overcoat layer 319.

Alternatively, the second auxiliary electrode 376 can overlap and be in contact with the overcoat layer 319.

In addition, the contact hole 317a and the plurality of insulation patterns 320 can also be disposed in the opening 319a and can be spaced apart from the overcoat layer 319.

The light-emitting layer 344 and the second electrode 346 can be sequentially provided on the overcoat layer 319. The light-emitting layer 344 and the second electrode 346 can be formed over substantially the entire surface of the substrate 300.

The light-emitting layer 344 can be separated by the insulation patterns 320 having the reversely-inclined side surfaces, thereby forming the second auxiliary electrode 376 formed on the side surface of the insulation pattern 320.

On the other hand, the second electrode 346 may not be separated by the insulation pattern 320 and can be formed along the top and side surfaces of the insulation patterns 320. The second electrode 346 can be in contact with the second auxiliary electrode 376 on the side surface of the insulation pattern 320. The second electrode 346 can be electrically connected to the first auxiliary electrode 372 through the second auxiliary electrode 376.

In this case, the second electrode 346 can be in contact with the second auxiliary electrode 376 on all side surfaces of the insulation patterns 320, thereby increasing the contact area between the second electrode 346 and the second auxiliary electrode 376. Accordingly, the contact properties between the second electrode 346 and the second auxiliary electrode 376 can be improved.

As such, in the electroluminescent display device according to the third embodiment of the present disclosure, two auxiliary electrodes 372 and 376 can be provided, and the second auxiliary electrode 376 on the insulation pattern 320 can be in direct contact with the first auxiliary electrode 372 under the insulation pattern 320. Accordingly, the process margin can increase and the defect rates can be reduced compared to the first embodiment in which three auxiliary electrodes 172, 174, and 176 are provided.

A method of manufacturing the electroluminescent display device according to the third embodiment of the present disclosure can differ from the method of manufacturing the electroluminescent display device according to the first embodiment in that the steps of forming the first passivation layer 115 and the second auxiliary electrode 174 are omitted. For example, the electroluminescent display device according to the third embodiment of the present disclosure can be manufactured by substantially the same method as the electroluminescent display device according to the first embodiment shown in FIGS. 8A and 8B and FIGS. 8E to 8I, except for the steps/processes of FIGS. 8C and 8D.

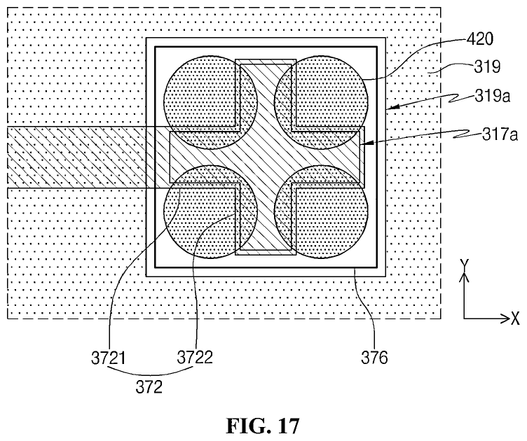

In the above embodiments, the insulation patterns 120 and 320 are described as having the rectangular shape in plan. However, embodiments of the present disclosure are not limited thereto. Such a fourth embodiment of the present disclosure will be described with reference to FIG. 17.

FIG. 17 is a schematic plan view of a contact area of an electroluminescent display device according to a fourth embodiment of the present disclosure. The electroluminescent display device according to the fourth embodiment of the present disclosure has substantially the same configuration as that of the third embodiment, except for a planar shape of the insulation pattern. The same parts as those of the third embodiment are designated by the same or similar reference signs/numerals, and explanation for the same parts can be shortened or omitted. The electroluminescent display device according to the fourth embodiment of the present disclosure has substantially the same cross-sectional structure as that of FIG. 16 and will be described with reference to FIG. 16 together.

As shown in FIG. 17, in the electroluminescent display device according to the fourth embodiment of the present disclosure, the first auxiliary electrode 372 can include the first portion 3721 and the second portion 3722 provided as one body, and the first auxiliary electrode 372 can have a cross shape with a plurality of L-like sides in plan.

The passivation layer 317 can be provided on the first auxiliary electrode 372. The passivation layer 317 can have the contact hole 317a exposing the top surface of the first auxiliary electrode 372, and the contact hole 317a can have a cross shape in plan.

The plurality of insulation patterns 420 can be provided on the passivation layer 317. The plurality of insulation patterns 420 can correspond to and overlap the L-like sides of the first auxiliary electrode 372, respectively.

Each insulation pattern 420 can have the reversely-inclined side surfaces and can have a circular shape in plan.

The second auxiliary electrode 376 can be disposed on the plurality of insulation patterns 420. The second auxiliary electrode 376 can cover the plurality of insulation patterns 420. The second auxiliary electrode 376 can be in contact with the first auxiliary electrode 372 exposed through the contact hole 317a between adjacent insulation patterns 420.

Meanwhile, the overcoat layer 319 can be provided on the second passivation layer 317. The overcoat layer 319 can have the opening 319a.

The first and second auxiliary electrodes 372 and 376 and the plurality of insulation patterns 420 can be disposed substantially in the opening 319a. The second auxiliary electrode 376 and the plurality of insulation patterns 420 can be spaced apart from the overcoat layer 319.

As such, in the electroluminescent display device according to the fourth embodiment of the present disclosure, the insulation pattern 420 can have the circular shape in plan. However, embodiments of the present disclosure are not limited thereto. The shape of the insulation pattern 420 can be configured in various ways as long as it corresponds to and overlaps the L-like side of the first auxiliary electrode 372.

In the electroluminescent display device according to aspects of the present disclosure, by connecting the second electrode of the light-emitting diode to the power line through the auxiliary electrode, the resistance of the second electrode can be reduced, and the luminance of the electroluminescent display device can be uniform.

In addition, the light-emitting layer according to aspects of the present disclosure can be separated by the insulation pattern and the second electrode can be in contact with the auxiliary electrode on the side surface of the insulation pattern, so that the contact area between the second electrode and the auxiliary electrode can increase compared to the undercut structure, thereby improving the contact property between the second electrode and the auxiliary electrode.

Accordingly, the luminance of the electroluminescent display device according to aspects of the present disclosure can be improved, and the improved luminance can reduce power consumption, thereby achieving the low power consumption.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. An electroluminescent display device, comprising:
a substrate provided with a sub-pixel including an emission area and a contact area;
a light-emitting diode provided in the emission area over the substrate, and including a first electrode, a light-emitting layer, and a second electrode;
a first auxiliary electrode provided in the contact area over the substrate;
a plurality of insulation patterns provided over the first auxiliary electrode and spaced apart from each other; and
a second auxiliary electrode covering the plurality of insulation patterns and electrically connected to the first auxiliary electrode,
wherein the light-emitting layer is separated by the plurality of insulation patterns to thereby expose the second auxiliary electrode, and the second electrode is in contact with the exposed second auxiliary electrode.

2. The electroluminescent display device of claim 1, wherein the first auxiliary electrode includes a first portion extending in a first direction and a second portion extending in a second direction different from the first direction.

3. The electroluminescent display device of claim 2, wherein the first auxiliary electrode has a plurality of L-like sides in plan.

4. The electroluminescent display device of claim 3, wherein the first auxiliary electrode has a cross shape in plan.

5. The electroluminescent display device of claim 3, wherein the plurality of insulation patterns correspond to and overlap the plurality of L-like sides, respectively.

6. The electroluminescent display device of claim 5, wherein the plurality of insulation patterns overlap side portions of each of the plurality of L-like sides.

7. The electroluminescent display device of claim 5, wherein the second auxiliary electrode covers each of the plurality of insulation patterns and each of the plurality of L-like sides.

8. The electroluminescent display device of claim 1, wherein each of the plurality of insulation patterns has a reversely-inclined side surface.

9. The electroluminescent display device of claim 8, wherein a top side of each of the plurality of insulation patterns has a wider width than a bottom side of the corresponding insulation pattern.

10. The electroluminescent display device of claim 8, wherein each side surface of each of the plurality of insulation patterns has an angle greater than 90 degrees with respect to a top surface of the substrate.

11. The electroluminescent display device of claim 1, wherein the second electrode is in contact with the second auxiliary electrode on a side surface of each of the plurality of insulation patterns.

12. The electroluminescent display device of claim 1, further comprising a passivation layer provided between the first auxiliary electrode and the plurality of insulation patterns, the passivation layer having a contact hole exposing the first auxiliary electrode,
wherein the second auxiliary electrode is in contact with the first auxiliary electrode through the contact hole between adjacent insulation patterns.

13. The electroluminescent display device of claim 12, wherein a width of the contact hole is greater than a distance between top sides of adjacent insulation patterns, and is smaller than a distance between bottom sides of the adjacent insulation patterns.

14. The electroluminescent display device of claim 1, further comprising a third auxiliary electrode provided between the first auxiliary electrode and the plurality of insulation patterns and being in contact with the first auxiliary electrode and the second auxiliary electrode.

15. The electroluminescent display device of claim 14, further comprising:
a first passivation layer provided between the first auxiliary electrode and the third auxiliary electrode, and having a first contact hole exposing the first auxiliary electrode; and
a second passivation layer provided between the third auxiliary electrode and the plurality of insulation patterns, and having a second contact hole exposing the third auxiliary electrode,
wherein the second auxiliary electrode is in contact with the third auxiliary electrode through the second contact hole between adjacent insulation patterns, and the third auxiliary electrode is in contact with the first auxiliary electrode through the first contact hole between adjacent insulation patterns.

16. The electroluminescent display device of claim 15, wherein each of the first contact hole, the second contact hole, and the third auxiliary electrode has a cross shape in plan.

17. The electroluminescent display device of claim 16, wherein the third auxiliary electrode has a cross shape in plan.

18. The electroluminescent display device of claim 15, wherein a distance between top sides of adjacent insulation patterns is greater than a width of the first contact hole and is smaller than a width of the second contact hole.

19. The electroluminescent display device of claim 1, further comprising an overcoat layer provided between the first auxiliary electrode and the light-emitting diode and having an opening corresponding to the contact area,
wherein the plurality of insulation patterns and the second auxiliary electrode are disposed in the opening.

20. The electroluminescent display device of claim 19, wherein the plurality of insulation patterns are spaced apart from the overcoat layer.

21. The electroluminescent display device of claim 19, wherein the plurality of insulation patterns are formed of the same material as the overcoat layer.

22. The electroluminescent display device of claim 19, wherein the opening and the second auxiliary electrode have a square shape or a rectangular shape in plan, to overlap all of the plurality of insulation patterns.

23. The electroluminescent display device of claim 1, wherein a plurality of sub-pixels are provided over the substrate, and
wherein in the contact area of at least one sub-pixel of the plurality of sub-pixels, the first auxiliary electrode is in contact with the second electrode.

24. The electroluminescent display device of claim 23, wherein in the contact area of the at least one sub-pixel, a portion of the first auxiliary electrode protrudes upward to pass through the second auxiliary electrode and the light-emitting layer, so as to be in contact with the second electrode.

25. The electroluminescent display device of claim 19, wherein the sub-pixel further includes a transparent area, and
wherein the overcoat layer is removed in the transparent area.

26. The electroluminescent display device of claim 1, wherein the first auxiliary electrode is electrically connected to a power line configured to provide a low potential voltage.

27. The electroluminescent display device of claim 1, wherein the second auxiliary electrode is continuously extended among the plurality of insulation patterns, to cover all side surfaces of the plurality of insulation patterns.

28. The electroluminescent display device of claim 1, wherein the second auxiliary electrode includes the same material as the first electrode.

29. The electroluminescent display device of claim 1, wherein the light-emitting layer is separated by the plurality of insulation patterns to thereby expose the second auxiliary electrode on side surfaces of the plurality of insulation patterns.

30. The electroluminescent display device of claim 1, wherein the second auxiliary electrode and the second auxiliary electrode are formed through a sputtering method, and the light-emitting layer is formed through a thermal evaporation method.

31. An electroluminescent display device, comprising:
a substrate provided with a plurality of sub-pixel each including an emission area, and sharing a contact area;
a light-emitting diode provided in the emission area over the substrate and including a first electrode, a light-emitting layer, and a second electrode;
a first auxiliary electrode provided in the contact area over the substrate;
a plurality of insulation patterns over the first auxiliary electrode and spaced apart from each other; and
a second auxiliary electrode covering the plurality of insulation patterns and electrically connected to the first auxiliary electrode,
wherein the light-emitting layer and the second electrode extend to the contact area, in which the light-emitting layer is separated by the plurality of insulation patterns to thereby expose the second auxiliary electrode, and the second electrode is in contact with the exposed second auxiliary electrode.
